(19) United States
(12) Patent Application Publication
(10) Pub. No.: US 2019/0067579 A1
(43) Pub. Date: Feb. 28, 2019

(54) VAPOR DEPOSITION APPARATUS, VAPOR DEPOSITION METHOD, AND METHOD FOR MANUFACTURING ORGANIC EL DISPLAY DEVICE

(71) Applicant: Sharp Kabushiki Kaisha, Sakai City, Osaka (JP)

(72) Inventors: Satoshi INOUE, Sakai City (JP); Shinichi KAWATO, Sakai City (JP); Yuhki KOBAYASHI, Sakai City (JP)

(73) Assignee: Sharp Kabushiki Kaisha, Sakai city, Osaka (JP)

(21) Appl. No.: 16/080,046

(22) PCT Filed: Mar. 22, 2017
(86) PCT No.: PCT/JP2017/011521

§ 371 Date: Aug. 27, 2018

(30) Foreign Application Priority Data
Mar. 29, 2016 (JP) 2016-066710

(51) Int. Cl. H01L 51/00; C23C 14/04; C23C 14/24

(52) U.S. Cl. CPC H01L 51/0011; C23C 14/042; H01L 51/5012; H01L 51/001; C23C 14/24

(57) ABSTRACT

Provided is a vapor deposition apparatus capable of suppressing the occurrence of relatively large smudges not intended by design. In this vapor deposition apparatus, a recessed portion is provided in a scanning direction of a substrate in a region between two emission openings adjacent to each other on a limiting plate side of a top plate.

### TECHNICAL FIELD

The disclosure relates to a vapor deposition apparatus, a vapor deposition method, and a method for manufacturing an organic EL display device.

### BACKGROUND ART

Recent years, development of various types of flat panel displays has been witnessed. In particular, an organic electro luminescence (EL) display device has attracted much attention as an excellent flat panel display in terms of lower power consumption, thinner size, and higher picture quality, and has been recommended for development as a candidate for next-generation display technology.

In such a field of EL display devices, as in the field of liquid crystal display devices, an increase in the number of pixels per inch (ppi) in the display device is demanded for even higher picture quality. Accordingly, in the field of organic EL display devices, formation of a vapor deposition film that includes a light-emitting layer at a higher resolution on the substrate is demanded for an increase in the number of pixels per inch in the display device.

To form an organic EL element provided to an organic EL display device, a film formation process based on a vacuum vapor deposition technique is used. In particular, when forming an organic EL element on a large substrate, a scan vapor deposition technique (also referred to as a transport film formation technique) of performing vapor deposition while moving one of the large substrate and a vapor deposition unit having a size smaller than the large substrate relatively to the other is considered promising.

PTL 1 describes a vapor deposition particle emitting portion provided to a vapor deposition unit of a vapor deposition apparatus used in such scan vapor deposition.

FIG. 15 is a diagram illustrating a general configuration of the vapor deposition unit provided to the known vapor deposition apparatus of disclosed in PTL 1.

As illustrated, a housing 127 of a vapor deposition unit 104 includes, on an inner side, a nozzle 134 serving as a jetting hole for vapor, and contains a crucible 122 in which a vapor deposition material 121 is enclosed.

Further, the housing 127 includes, on the inner side, a heater 123 that heats the crucible 122 and the vapor deposition material 121, and a heat insulating means 140 that surrounds the crucible 122 and the heater 123.

Furthermore, partition plates 150 made of a highly thermoconductive material are provided in a nozzle arrangement direction of the crucible 122, dividing the crucible 122 into a plurality of sections for storing the vapor deposition material 121. Material evaporation spaces 151 are then individually formed in each section between the partition plates 150 by an inner lid 133 made of a same highly thermoconductive material with the partition plates 150 and provided with an orifice 139, thereby restricting the input and output of vapor between adjacent spaces.

Further, in the vapor deposition unit 104, a vapor diffuser and rectifier plate 152 is provided as a partition in a space between the material evaporation space 151 and the nozzle 134 as a vapor diffuser for diffusing the vapor in a longitudinal direction.

This vapor diffuser and rectifier plate 152 is configured to separate the area between the material evaporation space 151 and the nozzle 134 into a vapor diffusion space 154 and a vapor supply buffer space 155. With such a configuration, the vapor from the material evaporation space 151 is dispersed in the vapor diffusion space 154, moved left and right, and then moved to the vapor supply buffer space 155 via the orifice 153 provided to the vapor diffuser and rectifier plate 152, and externally discharged from the nozzle 134.

PTL 1 thus states that, according to such a configuration, in a long vapor deposition unit, it is possible to realize a linear-type vapor deposition unit that achieves a film thickness distribution having favorable reproducibility during operation over a long period, from the start of processing.

### CITATION LIST

### Patent Literature

PTL 1: JP 2015-10257 A (published Jan. 19, 2015).

### SUMMARY

### Technical Problem

The crucible 122 of the vapor deposition particle emitting portion provided to the vapor deposition unit 104 disclosed in PTL 1 and illustrated in FIG. 15 includes a top plate on which the nozzles 134 are linearly arranged.

Nevertheless, as illustrated in FIG. 15, on the top plate of the crucible 122, the region between the nozzles 134 adjacent to each other is level.

Further, as the vapor deposition particles emitted from the nozzles 134 of the vapor deposition unit 104 extend in a separate patterning direction as well, the use of a limiting plate that prevents the vapor deposition particles from spreading in the separate patterning direction to a predetermined width or greater and being vapor-deposited on the substrate is required to form a high-resolution vapor deposition film in the separate patterning direction.

Below are described the problems that may occur when a vapor deposition film is formed on a substrate using a vapor deposition unit that includes a vapor deposition particle emitting portion provided with a top plate having a level region between adjacent emission openings (nozzles), and a limiting plate in the known vapor deposition apparatus, with reference to FIGS. 16A to 18B.

FIGS. 16A and 16B are diagrams for explaining the problems of a known vapor deposition unit 70 that includes a vapor deposition particle emitting portion 56 provided with a top plate 56S having a level region between emission openings 57 adjacent to each other, and that is used for scan vapor deposition.

FIG. 16A illustrates a case where a vapor deposition film 62R is formed on a substrate 61 using the vapor deposition unit 70 not provided with a vapor deposition mask in the known vapor deposition apparatus, and FIG. 16B illustrates smudges not intended by design that pattern is other than the designed pattern occurring as a result of this case.

As illustrated in FIG. 16A, the known vapor deposition unit 70 includes a plurality of limiting plates 59 and the vapor deposition particle emitting portion 56 including the top plate 56S provided with a plurality of the emission openings 57 that emit vapor deposition particles arranged linearly in a separate patterning direction, which is the left-right direction in the diagram.

The plurality of limiting plates 59 are provided above the vapor deposition particle emitting portion 56, separated by a predetermined distance from the top plate 56S of the vapor deposition particle emitting portion 56. Then, a space between two of the limiting plates 59 adjacent to each other is formed to a size greater than that of the emission opening 57, the limiting plate 59 is disposed above the region between the two emission openings 57 adjacent to each other, and a space between the limiting plates 59 is disposed above the emission openings 57.

The substrate 61 is provided above the plurality of limiting plates 59, separated by a predetermined distance from upper faces 59H of the limiting plates 59.

Thus, the vapor deposition particles emitted from the plurality of emission openings 57 of the vapor deposition particle emitting portion 56 are vapor-deposited on the substrate 61 via the spaces between the plurality of limiting plates 59.

Then, with the vapor deposition unit 70 fixed as is, the substrate 61 is scanned (transported) in a scanning direction of the substrate (the depth direction in the diagram), making it possible to form the vapor deposition film 62R having a predetermined thickness in the film thickness direction in the diagram and a linear pattern in the scanning direction of the substrate on the substrate 61.

While the limiting plates 59 prevent the vapor deposition particles from spreading in the separate patterning direction to a predetermined width or greater and being vapor-deposited on the substrate 61, as illustrated in FIG. 16B, when the known vapor deposition unit 70 is used, smudges not intended by design, i.e., a pattern shape not intended by design, with a width extending in the separate patterning direction occur, resulting in the problem that the vapor deposition film 62R having a shape with a width that extends in the separate patterning direction unlike the design pattern is formed on the substrate 61.

When the vapor deposition film 62R of an organic EL element is formed and such a problem occurs, an unnecessary vapor deposit film is formed on pixels adjacent in the separate patterning direction, resulting in the problem of a deterioration in element characteristics, such as a deterioration in a brightness or a service life of the organic EL elements of adjacent pixels.

To avoid such problems of deterioration in organic EL element characteristics, considering the smudges not intended by design described above, a design that widens the spaces between adjacent pixels is required, that makes the realization of a high-resolution organic EL display device difficult.

Below, the reason for the occurrence of smudges not intended by design in the vapor deposition film 62R in the known vapor deposition unit 70 will be described.

As illustrated in FIG. 16A, the flow of vapor deposition particles vapor-deposited on the substrate 61 (hereinafter referred to as the “vapor deposition flow”) is not formed only by the vapor deposition particles emitted from the plurality of emission openings 57 of the vapor deposition particle emitting portion 56, but also includes, for example, a vapor deposition flow from the region A or the region B in the diagram.

The reason for the occurrence of the vapor deposition flow from the region A or the region B is as follows. While the vapor deposition particles emitted from the emission openings 57 partially adhere to lower faces 59L of the limiting plates 59, forming a vapor deposition layer 63, a portion of these vapor deposition particles scatter onto the limiting plate 59 side of the top plate 56S as a vapor deposition particle mass 64. The top plate 56S becomes high in temperature, causing the vapor deposition particle mass 64 on the surface of the top plate 56S side of the limiting plates 59 to evaporate once again, and the vapor deposition particles from the vapor deposition particle mass 64 to scatter in various directions and form the vapor deposition flow from the region A or the region B.

Thus, when the vapor deposition particle mass 64 exists in the region A or the region B of the surface of the top plate 56S on the limiting plate 59 side, or even in a region other than these regions, the vapor deposition flow from the region A or the region B occurs. That is, as long as the vapor deposition particle mass 64 exists on the surface of the top plate 56S on the limiting plate 59 side, the vapor deposition flow from the region A or the region B occurs.

The smudge portions not intended by design in FIG. 16B are not formed by effects based on the vapor deposition flow from the emission openings 57, but rather by effects based on the vapor deposition flow from the region A or the region B.

FIG. 17 is a diagram illustrating a case where the film thickness distribution in the separate patterning direction of the vapor deposition film 62R formed on the substrate 61 using the known vapor deposition unit 70 illustrated in FIG. 16A is normalized, given a maximum film thickness of 1.

In FIG. 17, the film thickness distribution in the separate patterning direction of the vapor deposition film 62R formed on the substrate 61 using the known vapor deposition unit 70 is indicated by a solid line, and the film thickness distribution in the separate patterning direction of an ideal design pattern of the shape originally targeted is indicated by an alternate long and short dash line.

This design pattern is determined by a width of the emission opening 57 in the separate patterning direction, a width of the space between two of the limiting plates 59 adjacent to each other, a distance between the lower face 59L of the limiting plate 59 and the emission opening 57, and the distance between the upper face 59H of the limiting plate 59 and the substrate 61.

Further, while both corner portions on an upper side of the design pattern indicated by the alternate long and short dash line have linear shapes, when the vapor deposition film 62R indicated by the solid line is actually formed, the shapes are curved due to the effects based on the vapor deposition flow from the region A or the region B.

Note that the film thickness distribution in the separate patterning direction in FIG. 17 is the result of measuring the vapor deposition film formed at a set film thickness of 200 nm using ellipsometry at a film formation rate of 6□/s using a silicon wafer as a substrate, the known vapor deposition unit 70, and a commercial quinolinol aluminum complex (Alq3) as a vapor deposition material.

As illustrated in FIG. 16B and FIG. 17, the film thickness distribution of the vapor deposition film 62R in the separate patterning direction spreads to a design expansion width or greater according to a width of the emission opening 57 in the separate patterning direction due to the effects of flying matter resulting from the effects of the scattering of the vapor deposition particles from the area surrounding the emission opening 57, that is, resulting from the effects of the vapor deposition flow from the region A or the region B, and this portion is observed as smudges not intended by design.

While a case where the vapor deposition unit 70 not provided with a vapor deposition mask was used as an example in the descriptions above, use of the vapor deposition unit 70 provided with a vapor deposition mask 60 results in similar problems as described below.

FIGS. 18A and 18B are diagrams for explaining the problems of a known vapor deposition unit 70a that includes the vapor deposition particle emitting portion 56 provided with the top plate 56S having a level region between the emission openings 57 adjacent to each other, and that is used for scan vapor deposition.

FIG. 18A illustrates a case where a vapor deposition film 63R is formed on the substrate 61 using the vapor deposition unit 70a provided with the vapor deposition mask 60 in the known vapor deposition apparatus, and FIG. 18B illustrates smudges not intended by design that pattern is other than the designed pattern occurring as a result of this case.

The vapor deposition unit 70a illustrated in FIG. 18A differs from the vapor deposition unit 70 illustrated in FIG. 16A in that the vapor deposition unit 70a includes the vapor deposition mask 60, provided with openings 60K, between the upper faces 59H of the limiting plates 59 and the substrate 61.

As illustrated in FIG. 18A, the openings 60K of the vapor deposition mask 60 are each formed in accordance with the position of the space between two of the limiting plates 59 adjacent to each other. Further, a size of the region A or the region B that affects the formation of smudges not intended by design varies according to the position of the opening 60K of the vapor deposition mask 60 with respect to the position of the space between the two limiting plates 59 adjacent to each other (in the vapor deposition unit 70 not provided with the vapor deposition mask 60 illustrated in FIG. 16A, the size of region A or region B that affects the formation of smudges not intended by design is the same).

As illustrated, considering the opening 60K of the vapor deposition mask 60 above the left end of the space between the two limiting plates 59 adjacent to each other in the diagram, the region A that affects the formation of smudges not intended by design is greater in size than the region B. On the other hand, although not illustrated, considering the opening 60K of the vapor deposition mask 60 above the right end of the space between the two limiting plates 59 adjacent to each other in the diagram, the region A that affects the formation of smudges not intended by design is smaller in size than the region B and, considering the opening 60K of the vapor deposition mask 60 above the substantial center in the separate patterning direction of the space between the two limiting plates 59 adjacent to each other, the region A and the region B that affect the formation of smudges not intended by design are substantially in equal in size.

Thus, the effects based on the vapor deposition flow from the region A or the region B can differ according to the position of the opening 60K of the vapor deposition mask 60 with respect to the position of the space between the two limiting plates 59 adjacent to each other. Accordingly, when the region A that affects the formation of smudges not intended by design is greater in size than the region B, the effect based on the vapor deposition flow from the region A is greater than the effect based on the vapor deposition flow from the region B and thus, as illustrated in FIG. 18B, the smudges not intended by design on the left side in the diagram are more widely formed in the separate patterning direction than the smudges not intended by design on the right side in the diagram.

As described above, while differences exist in the shape of the formed smudges not intended by design, even when the vapor deposition film 63R is formed on the substrate 61 using the vapor deposition unit 70a provided with the vapor deposition mask 60, the problem of the occurrence of smudges not intended by design occurs in the same manner as when the vapor deposition film 62R is formed on the substrate 61 using the vapor deposition unit 70 not provided with the vapor deposition mask 60.

As described above, when the vapor deposition film is formed on the substrate using a known vapor deposition unit that includes the vapor deposition particle emitting portion provided with a top plate having a level region between adjacent emission openings (nozzles), and a limiting plate, the problem arises that relatively large smudges not intended by design occur and a high-resolution vapor deposition film cannot be formed on the substrate.

In light of the above, an object of the disclosure is to provide a vapor deposition apparatus, a vapor deposition method, and a method for manufacturing an organic EL display device capable of suppressing the occurrence of relatively large smudges not intended by design.

### Solution to Problem

To solve the above-described problems, a vapor deposition apparatus according to the disclosure includes a vapor deposition particle emitting portion including a top plate linearly provided with a plurality of emission openings, being configured to emit vapor deposition particles, along with a first direction, and a plurality of limiting plates, wherein the plurality of emission openings are positioned in respective space between the plurality of limiting plates. The top plate includes a recessed portion on the limiting plate side, in a second direction orthogonal to the first direction, in a region between two of the emission openings adjacent to each other. The recessed portion includes at least one inclined face inclined with respect to the first direction. A perpendicular line perpendicular to at least a portion of the inclined face intersects the limiting plate.

According to such a configuration, because (a) the recessed portion is provided in the region between two of the emission openings adjacent to each other in the second direction orthogonal to the first direction, (b) the recessed portion includes at least one inclined face inclined with respect to the first direction, and (c) the perpendicular line perpendicular to at least a portion of the inclined face intersects the limiting plate, even when a portion of the vapor deposition particles emitted from the emission openings adhere to the limiting plates and then partially scatter to the limiting plate side of the top plate as a vapor deposition particle mass, and the top plate increases to a temperature higher than a sublimating temperature of a vapor deposition material used in the top plate, in the top plate on the limiting plate side, it is possible to limit the scattering direction of the vapor deposition particles from the vapor deposition particle mass in the recessed portion by the inclined face.

The amount of vapor deposition particles scattered from the vapor deposition particle mass of the recessed portion is greatest in the direction perpendicular to the inclined face, and the vapor deposition particles scattered in this direction adhere to the limiting plate.

Therefore, it is possible to decrease the amount of vapor deposition particles that pass through the spaces between the plurality of limiting plates from areas near the emission openings, and achieve a vapor deposition apparatus capable of suppressing the occurrence of relatively large smudges not intended by design.

To solve the above-described problems, a vapor deposition method according to the disclosure is a method including arranging a vapor deposition particle emitting portion including a top plate linearly provided with a plurality of emission openings configured to emit vapor deposition particles in a first direction, a plurality of limiting plates, a vapor deposition mask, and a substrate in that order from a bottom, and vapor-depositing vapor deposition particles emitted from the vapor deposition particle emitting portion on the substrate via spaces between the plurality of limiting plates and openings in the vapor deposition mask. The vapor-depositing is performed with the limiting plate disposed with respect to a recessed portion that is provided in a region between two of the emission openings adjacent to each other on the limiting plate side of the top plate, in a second direction orthogonal to the first direction, and that includes at least one inclined face inclined with respect to the first direction, causing a perpendicular line perpendicular to at least a portion of the inclined face to intersect the limiting plate.

According to the vapor deposition method described above, the vapor-depositing is performed with the limiting plate disposed with respect to the recessed portion that is provided in the region between two of the emission openings adjacent to each other on the limiting plate side of the top plate, in the second direction orthogonal to the first direction, and that includes at least one inclined face inclined with respect to the first direction, causing a perpendicular line perpendicular to at least a portion of the inclined face to intersect the limiting plate, thereby making it possible to decrease the amount of vapor deposition particles that pass from areas near the emission openings through the plurality of limiting plates, and achieve a vapor deposition method capable of suppressing the occurrence of relatively large smudges not intended by design.

To solve the above-described problems, a method for manufacturing an organic EL display device according to the disclosure is a method including a step for arranging a vapor deposition particle emitting portion including a top plate linearly provided with a plurality of emission openings configured to emit vapor deposition particles in a first direction, a plurality of limiting plates, a vapor deposition mask, and a substrate in that order from a bottom, and an organic EL element vapor deposition layer forming step for vapor-depositing vapor deposition particles emitted from the vapor deposition particle emitting portion on the substrate via spaces between the plurality of limiting plates and openings in the vapor deposition mask. The vapor-depositing in the organic EL element vapor deposition layer forming step is performed with the limiting plate disposed with respect to a recessed portion that is provided in a region between two of the emission openings adjacent to each other on the limiting plate side of the top plate, in a second direction orthogonal to the first direction, and that includes at least one inclined face inclined with respect to the first direction, causing a perpendicular line perpendicular to at least a portion of the inclined face to intersect the limiting plate.

According to the method for manufacturing an organic EL display device described above, in the organic EL element vapor deposition layer forming step, the vapor-depositing is performed with the limiting plate disposed with respect to the recessed portion that is provided in the region between two of the emission openings adjacent to each other on the limiting plate side of the top plate, in the second direction orthogonal to the first direction, and includes at least one inclined face inclined with respect to the first direction, causing a perpendicular line perpendicular to at least a portion of the inclined face to intersect the limiting plate, thereby making it possible to decrease the amount of vapor deposition particles that pass from areas near the emission openings through the plurality of limiting plates, and achieve a method for manufacturing an organic EL display device capable of suppressing the occurrence of relatively large smudges not intended by design.

### Advantageous Effects of Invention

According to a first aspect of the disclosure, it is possible to provide a vapor deposition apparatus, a vapor deposition method, and a method for manufacturing an organic EL display device capable of suppressing the occurrence of relatively large smudges not intended by design.

### BRIEF DESCRIPTION OF DRAWINGS

FIG. 1 is a diagram illustrating a schematic configuration of a vapor deposition apparatus according to a first embodiment of the disclosure.

FIG. 2 is a diagram illustrating a case where the vapor deposition apparatus illustrated in FIG. 1 is provided in vacuum chamber.

FIG. 3A is a diagram illustrating a case where a vapor deposition film is formed on a substrate without using a vapor deposition mask in the vapor deposition apparatus illustrated in FIG. 1.

FIG. 3B is a diagram illustrating a vapor deposition particle emitting portion provided to the vapor deposition apparatus illustrated in FIG. 1 as viewed from a substrate direction.

FIG. 4 is a diagram illustrating a case where a film thickness distribution in a separate patterning direction of a vapor deposition film formed on the substrate without using a vapor deposition mask in the vapor deposition apparatus illustrated in FIG. 1 is normalized, given a maximum film thickness of 1.

FIG. 5 is a diagram illustrating an example of a process for manufacturing an organic EL display device using the vapor deposition apparatus illustrated in FIG. 1.

FIGS. 6A to 6C are diagrams illustrating examples of a case where a light-emitting layer having a stripe shape included in the organic EL display device is formed using the vapor deposition apparatus illustrated in FIG. 1.

FIG. 7 is a diagram illustrating an example of a modification in the vapor deposition particle emitting portion provided to the vapor deposition apparatus illustrated in FIG. 1.

FIG. 8A is a diagram illustrating a case where the vapor deposition film is formed on the substrate without using a vapor deposition mask in the vapor deposition apparatus according to a second embodiment of the disclosure.

FIG. 8B is a diagram illustrating the vapor deposition particle emitting portion as viewed from the substrate direction.

FIG. 9 is a diagram illustrating a case where the film thickness distribution in the separate patterning direction of the vapor deposition film formed on the substrate without using a vapor deposition mask in the vapor deposition apparatus according to the second embodiment of the disclosure is normalized, given a maximum film thickness of 1.

FIG. 10A is a diagram illustrating a case where the vapor deposition film is formed on the substrate without using a vapor deposition mask in the vapor deposition apparatus according to a third embodiment of the disclosure.

FIG. 10B is a diagram illustrating the vapor deposition particle emitting portion as viewed from the substrate direction.

FIG. 11 is a diagram illustrating a case where the film thickness distribution in the separate patterning direction of the vapor deposition film formed on the substrate without using a vapor deposition mask in the vapor deposition apparatus according to the third embodiment of the disclosure is normalized, given a maximum film thickness of 1.

FIG. 12A is a diagram illustrating the vapor deposition particle emitting portion provided to the vapor deposition apparatus according to a forth embodiment of the disclosure.

FIG. 12B is a diagram illustrating the vapor deposition particle emitting portion as viewed from the substrate direction.

FIGS. 13A to 13C are diagrams illustrating an example of modifications of a recessed portion that can be provided to the vapor deposition particle emitting portion.

FIG. 14A is a diagram illustrating the vapor deposition particle emitting portion provided to the vapor deposition apparatus according to a fifth embodiment of the disclosure.

FIG. 14B is a diagram illustrating the vapor deposition particle emitting portion as viewed from the substrate direction.

FIG. 15 is a diagram illustrating a schematic configuration of the vapor deposition unit provided to the known vapor deposition apparatus disclosed in PTL 1.

FIG. 16A illustrates a case where the vapor deposition film is formed on the substrate using the vapor deposition unit not provided with a vapor deposition mask in the known vapor deposition apparatus.

FIG. 16B illustrates smudges not intended by design that pattern is other than the design pattern occurring as a result of the case.

FIG. 17 is a diagram illustrating a case where the film thickness distribution in the separate patterning direction of the vapor deposition film formed on the substrate using the vapor deposition unit not provided with a vapor deposition mask illustrated in FIG. 16A is normalized, given a maximum film thickness of 1.

FIG. 18A illustrates a case where the vapor deposition film is formed on the substrate using a vapor deposition unit 70a provided with a vapor deposition mask in the known vapor deposition apparatus.

FIG. 18B illustrates smudges not intended by design that pattern is other than the design pattern occurring as a result of the case.

### DESCRIPTION OF EMBODIMENTS

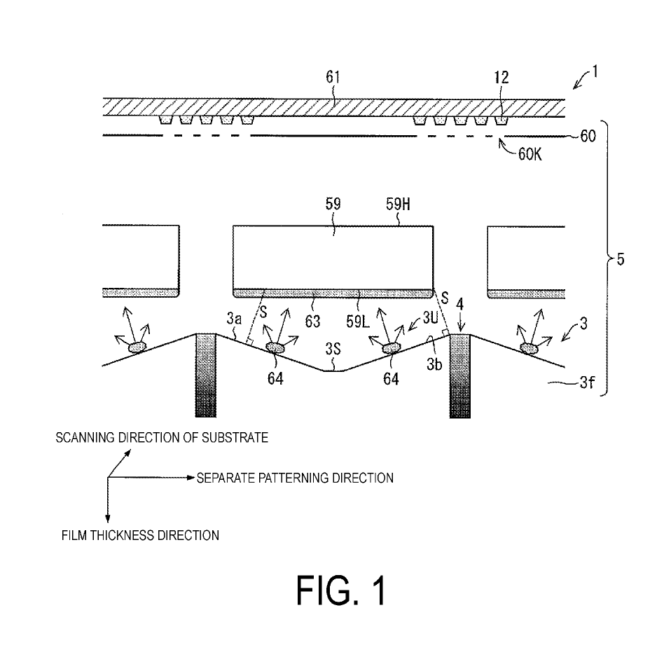

A description follows regarding embodiments of the disclosure, with reference to FIGS. 1 to 14B. Hereinafter, for convenience of descriptions, a configuration having the same functions as those of a configuration described in a specific embodiment are denoted by the same reference numerals, and its descriptions may be omitted.

Note that while, in each of the embodiments below, description is made of a vapor deposition apparatus and a vapor deposition method according to the disclosure using a manufacturing process of an organic EL display device as an example, the vapor deposition apparatus and the vapor deposition method according to the disclosure are not limited thereto and, needless to say, may be favorably used in various fields in which formation of a high-resolution vapor deposition film on a substrate is required.

### First Embodiment

A first embodiment of the disclosure will be described with reference to FIGS. 1 to 7.

FIG. 1 is a diagram illustrating a schematic configuration of a vapor deposition apparatus 1 that includes a vapor deposition particle emitting portion 3 provided with a recessed portion that includes inclined faces 3a, 3b in a region between two emission openings 4 adjacent to each other.

As illustrated, the vapor deposition apparatus 1 includes the substrate 61 and a vapor deposition unit 5, and the vapor deposition unit 5 includes the vapor deposition particle emitting portion 3, the plurality of limiting plates 59, and the vapor deposition mask 60.

Note that the vapor deposition particle emitting portion 3, the plurality of limiting plates 59, the vapor deposition mask 60, and the substrate 61 are disposed in the described order from a bottom in a film thickness direction in the diagram.

Then, the plurality of emission openings 4 of the vapor deposition particle emitting portion 3 are each respectively positioned in spaces between the plurality of limiting plates 59, and the limiting plates 59 are each disposed above the region between two of the emission openings 4 adjacent to each other.

Thus, the vapor deposition particles emitted from the plurality of emission openings 4 of the vapor deposition particle emitting portion 3 are vapor-deposited on the substrate 61 as a vapor deposition film 12 via the spaces between the plurality of limiting plates 59 and the openings 60K of the vapor deposition mask 60.

The vapor deposition particle emitting portion 3 includes a top plate 3f formed with the plurality of emission openings 4 configured to emit the vapor deposition particles linearly arranged in a separate patterning direction (a first direction) in the diagram, and the inclined face 3a, the inclined face 3b, and a planar face 3S are provided in a region between two of the emission openings 4 adjacent to each other on the limiting plate 59 side of the top plate 3f.

Specifically, on the limiting plate 59 side of the top plate 3f, a recessed portion 3U formed by the inclined face 3a, the inclined face 3b, and the planar face 3S is provided in a scanning direction (second direction) of the substrate orthogonal to the separate patterning direction in the diagram, in the region between two of the emission openings 4 adjacent to each other.

The inclined face 3a and the inclined face 3b are inclined faces, causing a perpendicular line S of the inclined face 3a and a perpendicular line S of the inclined face 3b to intersect the limiting plate 59 that exists directly above.

Specifically, the perpendicular lines S of large portions of the inclined face 3a and the inclined face 3b intersect the lower face 59L of the limiting plate 59 that exists directly above, and the perpendicular lines S of the inclined face 3a and the inclined face 3b near the emission openings 4 intersect side surfaces of the limiting plate 59.

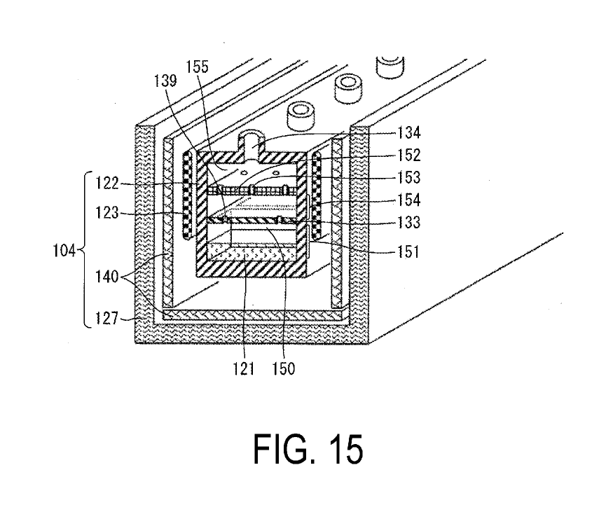

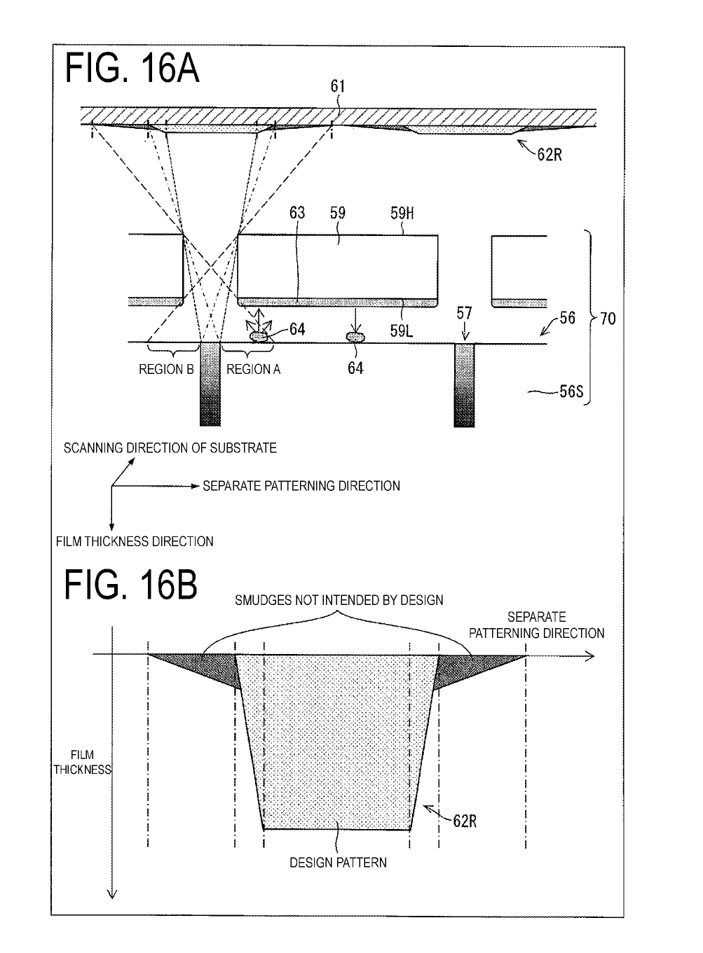

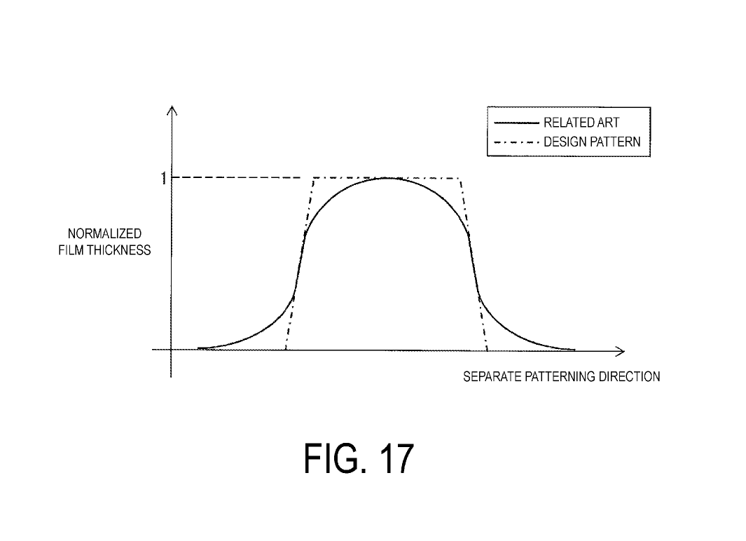

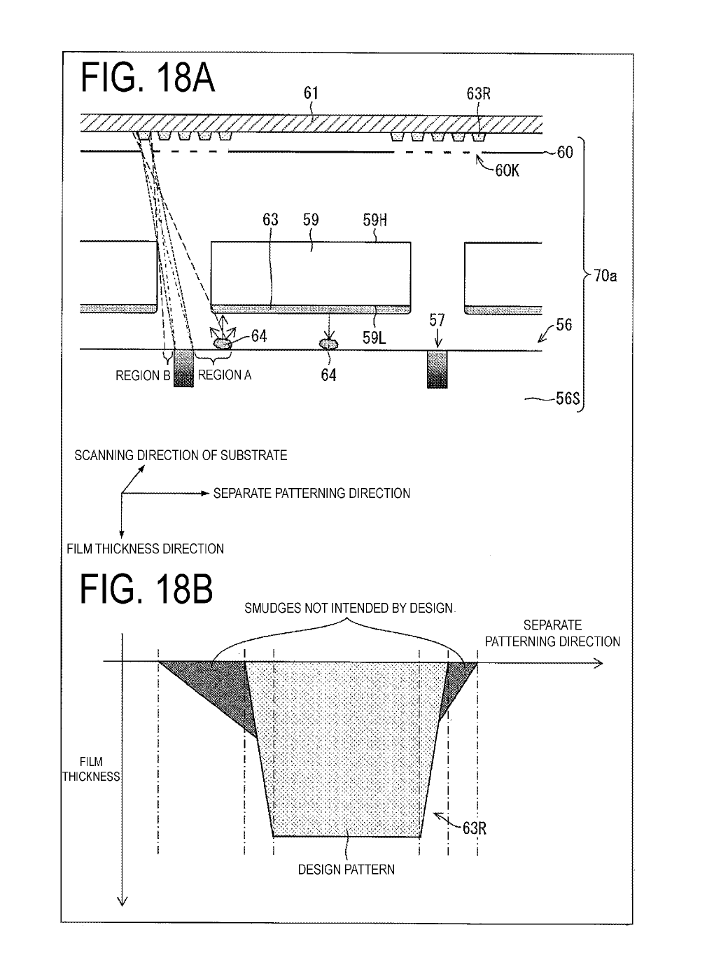

In the related art, while the region between two of the emission openings adjacent to each other is formed on a planar face (refer to FIG. 15, FIG. 16A, and FIG. 18A) on the limiting plate side of the top plate, in the present embodiment the recessed portion 3U formed by the inclined face 3a, the inclined face 3b, and the planar face 3S is provided in the region between the two emission openings 4 adjacent to each other on the limiting plate 59 side of the top plate 3f.

During use of the vapor deposition apparatus 1, a portion of the vapor deposition particles emitted from the emission openings 4 is adhered to side surfaces of the limiting plates 59 and the lower faces 59L, which is the surface facing the upper faces 59H, of the limiting plates 59, and subsequently partially scattered to the limiting plate 59 side of the top plate 3f including the inclined face 3a, the inclined face 3b, and the planar face 3S as the vapor deposition particle mass 64. Further, the top plate 3f that includes the inclined face 3a, the inclined face 3b, and the planar face 3S becomes higher in temperature than a sublimating temperature of the vapor deposition material used.

In such a case as well, in the region between two of the emission openings 4 adjacent to each other on the limiting plate 59 side of the top plate 3f in the vapor deposition particle emitting portion 3 of the vapor deposition apparatus 1, the recessed portion 3U formed by the inclined face 3a, the inclined face 3b, and the planar face 3S is provided in the scanning direction of the substrate orthogonal to the separate patterning direction in the diagram, making it possible to limit the scattering direction of the vapor deposition particles from the vapor deposition particle mass 64 in the recessed portion 3U by the inclined faces 3a, 3b.

Specifically, the inclined faces 3a, 3b are inclined, causing the perpendicular lines S of the inclined faces 3a, 3b to intersect the limiting plate 59 that exists directly above, making it possible to decrease an amount of vapor deposition particles that, from the vapor deposition particle mass 64 in the recessed portion 3U, reach near to the emission opening 4, and reduce a vapor deposition particle density near the emission opening 4, thereby suppressing the occurrence of relatively large smudges not intended by design.

Further, the recessed portion 3U includes at least a portion of a region where the region between the two emission openings 4 adjacent to each other and the space between the plurality of limiting plates 59 overlap in a plan view (including the entire overlapping region in the present embodiment), thereby making it possible to decrease the amount of vapor deposition particles that pass from areas near the emission openings 4 through the spaces between the plurality of limiting plates 59.

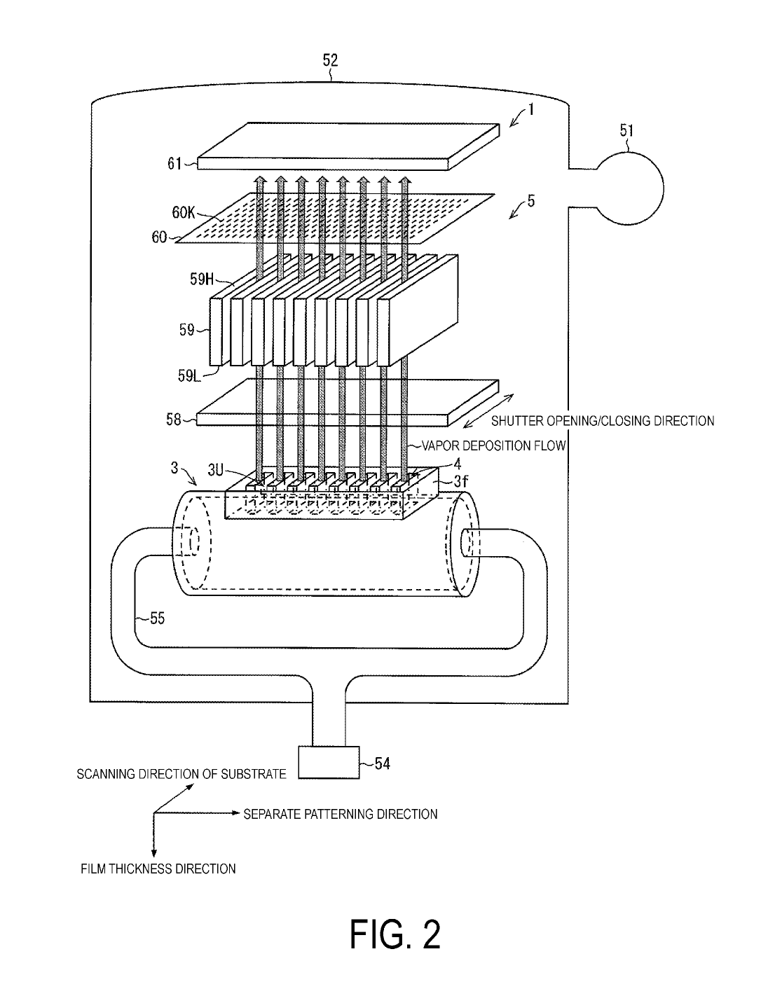

FIG. 2 is a diagram illustrating a case where the vapor deposition apparatus 1 is provided in a vacuum chamber 52.

As illustrated, the vapor deposition apparatus 1 is provided in the vacuum chamber 52 connected with a vacuum pump 51, making it possible to form the vapor deposition film 12, such as an organic film, for example, on the substrate 61 using a vacuum vapor deposition technique.

Note that, in the present embodiment, only the substrate 61 is scanned (transported) in the scanning direction of the substrate in the diagram, all other constituent members are fixed, and vapor-depositing is performed while only the substrate 61 is scanned in the scanning direction of the substrate in the diagram, making it possible to form, on the substrate 61, a vapor deposition film having a predetermined thickness in the film thickness direction in the diagram and a linear pattern in the scanning direction of the substrate 61.

A vapor deposition source 54 may be provided inside or outside the vacuum chamber 52, and is provided outside the vacuum chamber 52 in the present embodiment.

While, a crucible that sublimates a vapor deposition material (also called a film formation material) and generates vapor deposition particles as gas is used in the present embodiment as the vapor deposition source 54, the vapor deposition source is not limited thereto.

Note that, in the present embodiment, the vapor deposition source 54 is provided outside the vacuum chamber 52, and thus the vapor deposition source 54 outside the vacuum chamber 52 and the vapor deposition particle emitting portion 3 inside the vacuum chamber 52 are coupled using a pipe 55.

Further, internal temperatures of the pipe 55 and the vapor deposition particle emitting portion 3 are preferably set at least 50° C. higher than the sublimating temperature of the vapor deposition material and, for example, when the sublimating temperature of the vapor deposition material used is 350° C., the internal temperatures are preferably set to the sufficiently higher temperature of 400° C. or higher.

Note that, as illustrated, in addition to the vapor deposition particle emitting portion 3, the plurality of limiting plates 59, and the vapor deposition mask 60, the vapor deposition unit 5 includes a shutter 58 provided between the vapor deposition particle emitting portion 3 and the plurality of limiting plates 59, as well as the vapor deposition source 54 and the pipe 55 described above.

The shutter 58 is disposed in a closed position, for example, while the starting period of vapor deposition when the initial vapor deposition flow is unstable, and at the end of vapor deposition when the vapor deposition flow undesirably reach the substrate 61, stopping the vapor deposition flow from reaching the substrate 61, and is disposed in an open position during normal vapor deposition periods, allowing the vapor deposition flow to pass as is.

While, in the present embodiment, the opening/closing direction of the shutter 58 is described as the same as the scanning direction of the substrate in the diagram as an example, the opening/closing direction of the shutter 58 is not limited thereto and, for example, may be the separate patterning direction in the diagram.

Note that the limiting plates 59 prevent the vapor deposition particles from spreading to a predetermined width or greater in the separate patterning direction and being vapor-deposited on the substrate 61, the vapor deposition mask 60 is smaller in size than the substrate 61, and a plurality of the openings 60K corresponding to the pattern of the vapor deposition film to be formed on the substrate 61 are provided.

While, in the present embodiment, a case where vapor-depositing is performed while the substrate 61 is scanned in the scanning direction of the substrate in the diagram with respect to the vapor deposition unit 5 that is fixed is described as an example, the embodiment is not limited thereto, and vapor-depositing may be performed while scanning the vapor deposition unit 5 in the scanning direction of the substrate in the diagram with respect to the substrate 61 that is fixed.

Furthermore, in a case where the vapor deposition unit 5 and the substrate 61 are scanned in the same direction or different directions, vapor-depositing may be performed while relatively moving one of the vapor deposition unit 5 and the substrate 61 with respect to the other.

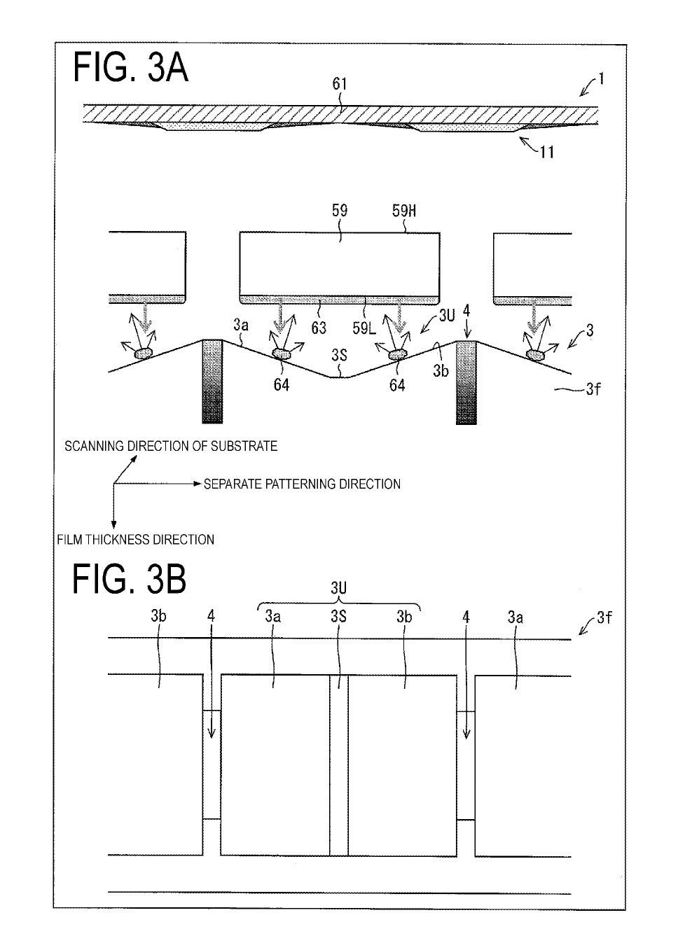

FIG. 3A is a diagram illustrating a case where a vapor deposition film 11 is formed on the substrate 61 in the vapor deposition apparatus 1 without using the vapor deposition mask 60.

FIG. 3B is a diagram illustrating the vapor deposition particle emitting portion 3 provided to the vapor deposition apparatus 1 as viewed from the substrate 61 direction.

As illustrated in FIGS. 3A and 3B, the emission openings 4 are each formed into a shape having a width in the scanning direction of the substrate that is greater than a width in the separate patterning direction.

Then, on the limiting plate 59 side of the top plate 3f of the vapor deposition particle emitting portion 3, the emission openings 4 each protrude to the substrate 61 side.

Note that, in the present embodiment, the emission opening 4 used has a width of 3 mm in the separate patterning direction, a width of 60 mm in the scanning direction of the substrate, and a depth of 60 mm. Further, a distance between two of the emission openings 4 adjacent to each other is 30 mm, and a distance from a height of the emission opening 4 to a height of the lower face 59L of the limiting plate 59 is 50 mm. Further, a pitch of the spaces between the limiting plates 59 is 30 mm, the same as the distance between the two emission openings 4 adjacent to each other, a distance between the lower faces 59L of two of the limiting plates 59 adjacent to each other, that is, a space width between the limiting plates 59, is 6 mm, and a distance from the height of the emission opening 4 to a height of the planar face 3S, that is, a depth of the recessed portion 3U, is 10 mm. Further, a distance from the emission opening 4 to the substrate 61 is 200 mm, and a height of the limiting plate 59 used is 30 mm. These values are merely examples, and naturally may be changed as appropriate, as necessary.

As illustrated in FIG. 3B, the top plate 3f includes the plurality of emission openings 4 linearly arranged in the separate patterning direction in the diagram and configured to emit the vapor deposition particles, as well as the recessed portion 3U that includes the inclined face 3a, the inclined face 3b, and the planar face 3S and provided in the scanning direction of the substrate orthogonal to the separate patterning direction in the diagram, in a region between two of the emission openings 4 adjacent to each other, on the limiting plate 59 side of the top plate 3f.

Note that while, in the present embodiment, the width of the recessed portion 3U in the scanning direction is formed greater than the width of the emission opening 4 in the scanning direction, the width of the recessed portion 3U in the scanning direction is not limited thereto, and may be less than or equal to the width of the emission opening 4 in the scanning direction.

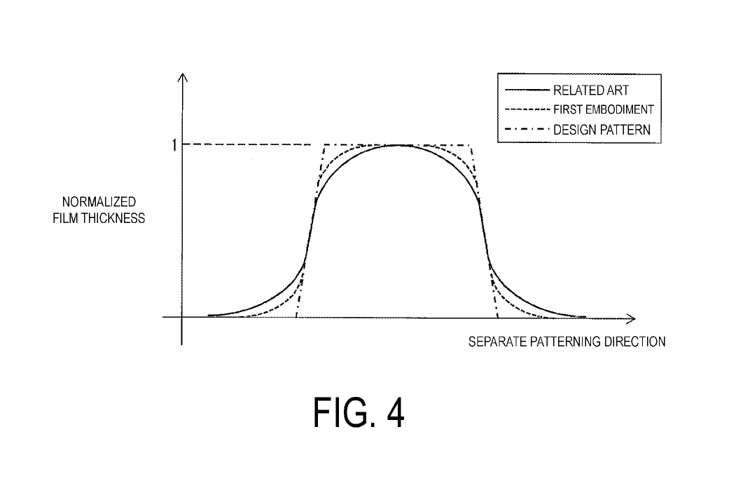

FIG. 4 is a diagram illustrating a case where a film thickness distribution in the separate patterning direction of the vapor deposition film 11 formed on the substrate 61 without using the vapor deposition mask 60 in the vapor deposition apparatus 1 is normalized, given a maximum film thickness of 1, as illustrated in FIG. 3A.

The alternate long and short dash line in the diagram indicates the design pattern, and this design pattern is an ideal pattern determined by the width of the emission opening 4 in the separate patterning direction, the width of the space between two of the limiting plates 59 adjacent to each other, a distance between the lower face 59L of the limiting plate 59 and the emission opening 4, and the distance between the upper face 59H of the limiting plate 59 and the substrate 61.

The solid line in the diagram is the pattern of the vapor deposition film obtained using the known vapor deposition apparatus illustrated in FIG. 16A, and the dashed line in the figure is the pattern of the vapor deposition film 11 formed on the substrate 61 without using the vapor deposition mask 60 in the vapor deposition apparatus 1, as illustrated in FIG. 3A.

As illustrated, in the pattern of the vapor deposition film 11 formed on the substrate 61 without using the vapor deposition mask 60 in the vapor deposition apparatus 1, the smudges not intended by design in the separate patterning direction are small compared to those in the pattern of the vapor deposition film obtained using the known vapor deposition apparatus, resulting in a pattern close to the design pattern, which is the ideal pattern.

This is because the inclined faces 3a, 3b of the vapor deposition particle emitting portion 3 of the vapor deposition apparatus 1 are inclined, causing the perpendicular lines S of the inclined faces 3a, 3b to intersect the limiting plate 59 that exists directly above, making it possible to decrease an amount of the vapor deposition particles from the vapor deposition particle mass 64 in the recessed portion 3U that reaches near to the emission opening 4 and reduce a vapor deposition particle density near the emission opening 4, thereby suppressing the occurrence of relatively large smudges not intended by design.

Note that the film thickness distribution in the separate patterning direction of the vapor deposition apparatus 11 illustrated in FIG. 4 is the result of measuring the vapor deposition film 11 formed at a set film thickness of 200 nm using ellipsometry at a film formation rate of 6□/s using a silicon wafer as a substrate, the vapor deposition apparatus 1 (without use of the vapor deposition mask 60), and a commercial quinolinol aluminum complex (Alq3) as a vapor deposition material.

While the above has described a case where, in the vapor deposition apparatus 1, the vapor deposition film 11 is formed on the substrate 61 without using the vapor deposition mask 60, even in a case where the vapor deposition film is formed on the substrate 61 in the vapor deposition apparatus 1 using the vapor deposition mask 60, the smudges not intended by design in the separate patterning direction are small and a pattern obtained to be closer to the design pattern, which is the ideal pattern compared to those of the vapor deposition film formed in the known vapor deposition apparatus using the vapor deposition mask.

As clearly understood from the relationship between FIGS. 16A, 16B and FIGS. 18A, 18B described above as well, in a case where smudges not intended by design occur in the vapor deposition film formed on the substrate without using the vapor deposition mask, smudges not intended by design will occur even when the vapor deposition mask is used, although the shape of the smudges is different.

Thus, as long as smudges not intended by design are suppressed in the vapor deposition film formed on the substrate without using the vapor deposition mask, the smudges not intended by design can also be suppressed in the vapor deposition film formed on the substrate using the vapor deposition mask. Thus, in the present embodiment as well as each of the embodiments hereinafter, only the results of suppressing smudges not intended by design in the vapor deposition film formed on the substrate without using the vapor deposition mask are described, and the results of suppressing smudges not intended by design in the vapor deposition film formed on the substrate using the vapor deposition mask are omitted.

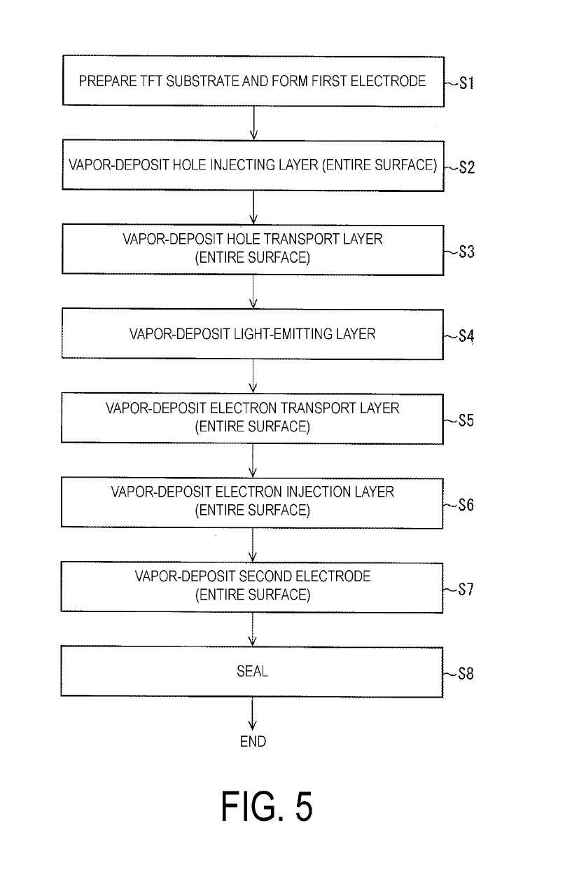

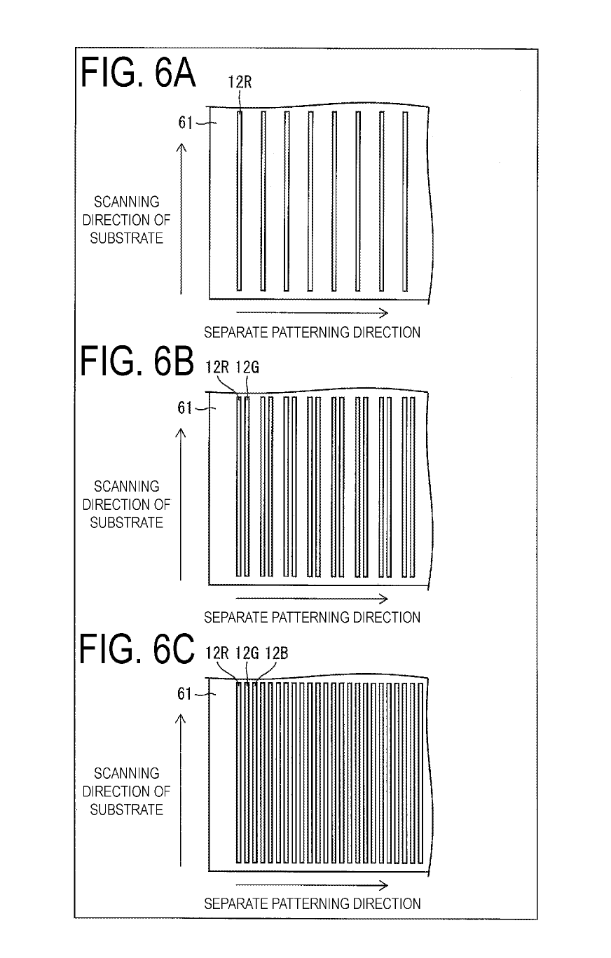

Below is described the process of manufacturing the organic EL display device using the vapor deposition apparatus 1 based on FIGS. 5 to 6C.

FIG. 5 is a diagram illustrating an example of the process for manufacturing the organic EL display device using the vapor deposition apparatus 1.

FIGS. 6A to 6C are diagrams illustrating cases where a light-emitting layer is formed on the substrate 61 using the vapor deposition apparatus 1.

First, a TFT element is prepared (TFT substrate preparation) on the substrate 61, and then a first electrode is formed (51).

Then, a hole injection layer and a hole transport layer are formed across the entire surface of the substrate 61 by a vacuum vapor deposition technique (S2, S3).

Subsequently, a light-emitting layer is formed in a predetermined location by a vacuum vapor deposition technique using the vapor deposition apparatus 1 (S4).

As illustrated in FIGS. 6A to 6C, in step S4, a red light-emitting layer 12R, a green light-emitting layer 12G, and a blue light-emitting layer 12B, each having the same width in the separate patterning direction and a linear shape extending in the scanning direction of the substrate, are separately formed in sequence in the separate patterning direction, and the red light-emitting layer 12R, the green light-emitting layer 12G, and the blue light-emitting layer 12B are formed from one end to the other end of the substrate in a striped pattern (striped) in the scanning direction of the substrate.

Subsequently, an electron transport layer, an electron injection layer, and a second electrode are formed across the entire surface by a vacuum vapor deposition technique in a described order (S5, S6, S7).

As described above, the region (display portion) of the organic EL element is sealed to the substrate 61, on which vapor deposition has been completed, to prevent deterioration of the organic EL element by moisture and oxygen in the atmosphere (S8).

The sealing is performed by forming a film not susceptible to moisture or oxygen permeation using a chemical vapor deposition (CVD) method, or by adhering glass substrates or the like together using an adhesive or the like.

According to the process described above, the organic EL display device is prepared and electric current is introduced from a driving circuit formed on the outside to organic EL elements in individual pixels to emit light, making it possible to achieve a preferred display.

### Modification

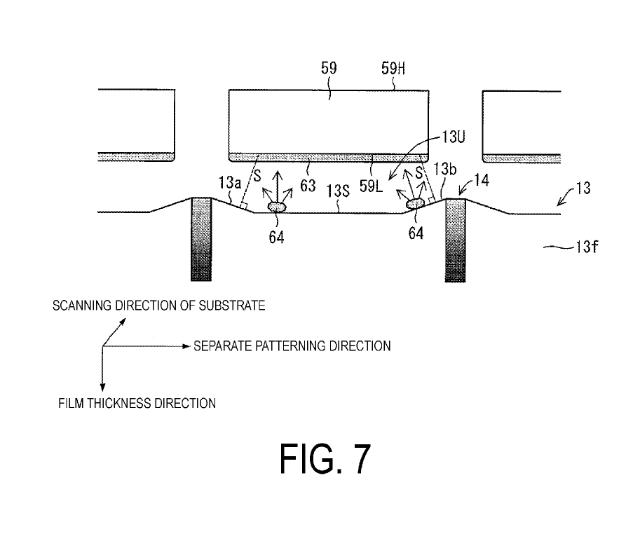

FIG. 7 is a diagram illustrating a vapor deposition particle emitting portion 13 that can be used in place of the vapor deposition particle emitting portion 3 in the vapor deposition apparatus 1.

While, in the recessed portion 3U that is provided on the limiting plate 59 side of the top plate 3f of the vapor deposition particle emitting portion 3 described above and that includes the inclined face 3a, the inclined face 3b, and the planar face 3S, a length of the inclined faces 3a, 3b is greater than that of the planar face 3S, and a ratio occupied by the inclined faces within the recessed portion 3U is large, in the recessed portion 13U that is provided on the limiting plate 59 side of the top plate 13f of the vapor deposition particle emitting portion 13 described above and that includes the inclined face 13a, the inclined face 13b, and the planar face 13S as illustrated in FIG. 7, a length of the inclined faces 13a, 13b is less than that of a planar face 13S, and the ratio occupied by the inclined faces within a recessed portion 13U is small.

In the vapor deposition particle emitting portion 13 as well, the inclined faces 13a, 13b are inclined, causing the perpendicular lines S of the inclined faces 13a, 13b to intersect the limiting plate 59 that exists directly above, making it possible to decrease the amount of vapor deposition particles that, from the vapor deposition particle mass 64 in the recessed portion 13U, reach near to an emission opening 14, and reduce a vapor deposition particle density near the emission opening 14, thereby suppressing the occurrence of relatively large smudges not intended by design.

Further, the recessed portion 13U includes a region where the region between the two emission openings 14 adjacent to each other and the space between the plurality of limiting plates 59 overlap in a plan view, thereby making it possible to reduce the amount of vapor deposition particles that pass from areas near the emission openings 14 through the spaces between the plurality of limiting plates 59.

Note that while, in the present embodiment, a case where the recessed portion includes two inclined faces and one planar face was described as an example, the shape is not limited thereto as long as the recessed portion includes an inclined face inclined with respect to the separate patterning direction, causing the perpendicular line S to intersect the limiting plate 59 that exists directly above.

Further, in the present embodiment, to form a more uniform vapor deposition film, the recessed portion 3U is symmetrically provided in the separate patterning direction about the center of the emission opening 4, the arrangement is not limited thereto.

### Second Embodiment

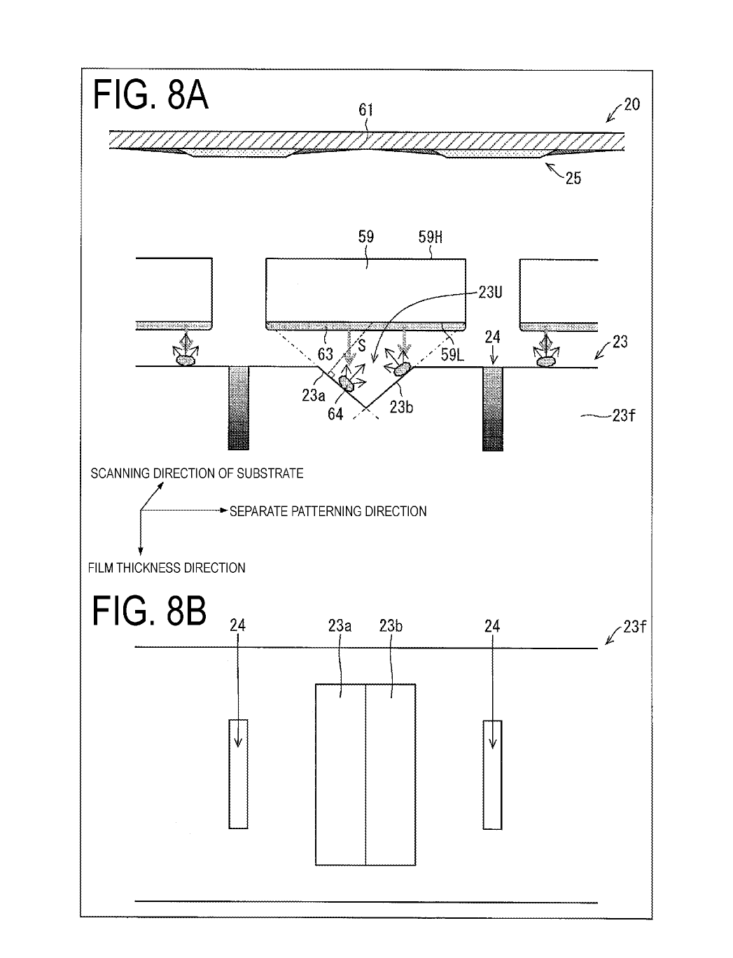

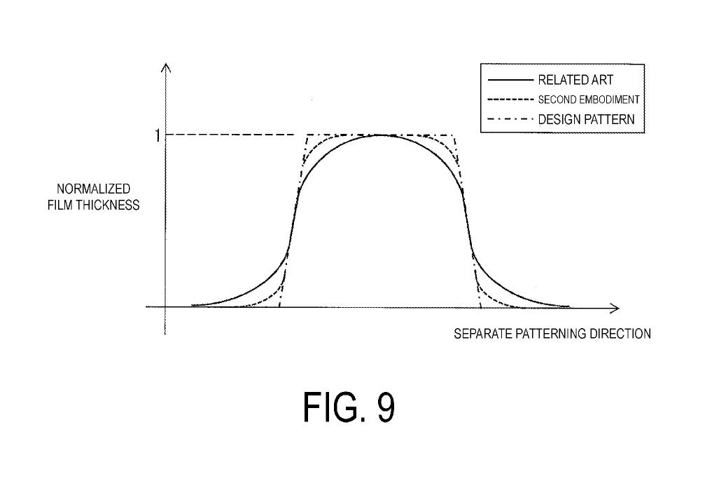

Next, a second embodiment of the disclosure will be described with reference to FIGS. 8A to 9. The present embodiment differs from the first embodiment in that a recessed portion 23U that includes inclined faces 23a, 23b is provided partially, and not entirely, across the region between two emission openings 24 adjacent to each other in the separate patterning direction, and the recessed portion 23U that includes the inclined faces 23a, 23b only, that is, the recessed portion 23U is formed in a reverse wedge-like shape. All other components are as described in the first embodiment. For convenience of descriptions, members having the same functions as those of the members illustrated in the diagrams in the first embodiment are denoted by the same reference numerals, and descriptions thereof will be omitted.

FIG. 8A is a diagram illustrating a case where a vapor deposition film 25 is formed on the substrate 61 without using a vapor deposition mask in a vapor deposition apparatus 20.

FIG. 8B is a diagram illustrating a vapor deposition particle emitting portion 23 as viewed from the substrate direction.

As illustrated in FIGS. 8A and 8B, the emission openings 24 are each formed into a shape having a width in the scanning direction of the substrate that is greater than a width in the separate patterning direction, and has a width in the separate patterning direction of 3 mm, a width in the scanning direction of the substrate of 60 mm, and a depth of 60 mm.

Then, the recessed portion 23U including the inclined faces 23a, 23b is provided partially, and not entirely, across the region between two of the emission openings 24 adjacent to each other on the limiting plate 59 side of the top plate 23f in the separate patterning direction. While, in the present embodiment, a planar portion is provided every 11.5 mm from each of the emission openings 24 adjacent to each other to the recessed portion 23U therebetween in the separate patterning direction, the embodiment is not limited thereto.

The recessed portion 23U is formed into a reverse wedge-like shape and, while in the present embodiment, is formed at a depth of 10 mm and a width in the separate patterning direction of 4 mm, the embodiment is not limited thereto.

Note that the inclined face 23a and the inclined face 23b are inclined, causing the perpendicular lines S of the inclined faces 23a, 23b to intersect the lower face 59L of the limiting plate 59 that exist directly above.

Further, the inclined face 23a is provided facing the inclined face 23b.

Then, in the present embodiment, extended planes respectively extending from the inclined faces 23a, 23b in the limiting plate 59 direction intersect both ends in the separate patterning direction of the lower face 59L of the limiting plate 59 that exists directly above the region between the two emission openings 24 adjacent to each other. However, the embodiment is not limited thereto.

Thus, the vapor deposition particles vapor-deposited once again from the vapor deposition particle mass 64 in the recessed portion 23U do not spread to the outer side of the extended planes, making it possible to suppress the scattering of vapor deposition particles to areas near the emission opening 24.

That is, the amount of vapor deposition particles that, from the vapor deposition particle mass 64 in the recessed portion 23U, reach near to the emission opening 24 can be decreased, and the vapor deposition particle density near the emission opening 24 can be reduced, thereby making it possible to suppress the occurrence of relatively large smudges not intended by design.

FIG. 9 is a diagram illustrating a case where the film thickness distribution in the separate patterning direction of the vapor deposition film 25 formed on the substrate 61 without using a vapor deposition mask in the vapor deposition apparatus 20 is normalized, given a maximum film thickness of 1, as illustrated in FIG. 8A.

The alternate long and short dash line in the diagram indicates the design pattern, and this design pattern is an ideal pattern determined by the width of the emission opening 24 in the separate patterning direction, the width of the space between two of the limiting plates 59 adjacent to each other, the distance between the lower face 59L of the limiting plate 59 and the emission opening 24, and the distance between the upper face 59H of the limiting plate 59 and the substrate 61.

The solid line in the diagram is the pattern of the vapor deposition film obtained using the known vapor deposition apparatus illustrated in FIG. 16A, and the dashed line in the figure is the pattern of the vapor deposition film 25 formed on the substrate 61 in the vapor deposition apparatus 20 without using a vapor deposition mask, as illustrated in FIG. 8A.

As illustrated, in the pattern of the vapor deposition film 25 formed on the substrate 61 in the vapor deposition apparatus 20 without using a vapor deposition mask, the smudges not intended by design in the separate patterning direction are small compared to those in the pattern of the vapor deposition film obtained using the known vapor deposition apparatus, resulting in a pattern close to the design pattern, which is the ideal pattern.

### Third Embodiment

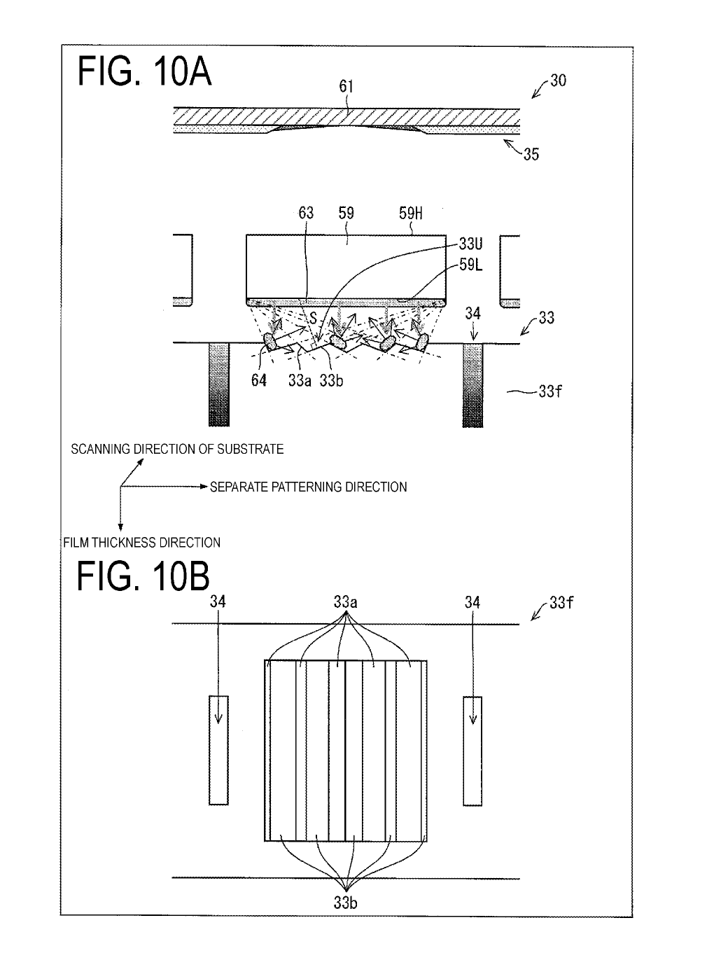

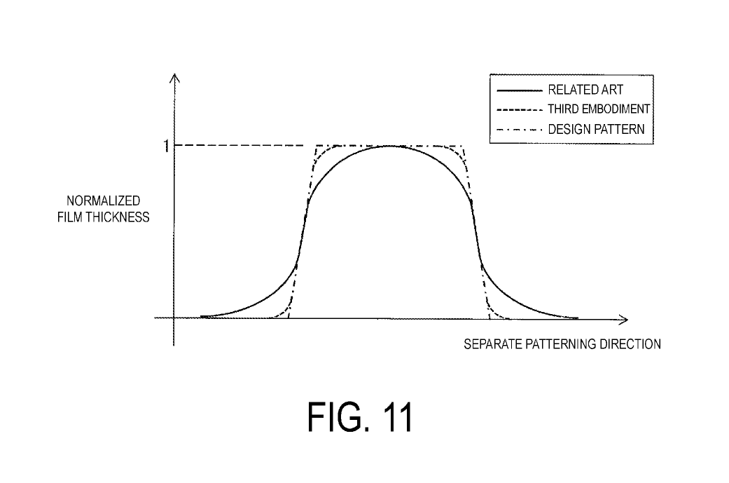

Next, a third embodiment of the disclosure will be described with reference to FIGS. 10A to 11. The present embodiment differs from the first and second embodiments in that a plurality of recessed portions 33U are provided in the separate patterning direction of the region between two emission openings 34 adjacent to each other. All other components are as described in the first and second embodiments. For convenience of descriptions, members having the same functions as those of the members illustrated in the diagrams in the first and second embodiments are denoted by the same reference numerals, and descriptions thereof will be omitted.

FIG. 10A is a diagram illustrating a case where a vapor deposition film 35 is formed on the substrate 61 in a vapor deposition apparatus 30 without using a vapor deposition mask.

FIG. 10B is a diagram illustrating a vapor deposition particle emitting portion 33 as viewed from the substrate direction.

As illustrated in FIGS. 10A and 10B, emission openings 34 are each formed into a shape having a width in the scanning direction of the substrate that is greater than a width in the separate patterning direction.

Then, the plurality of recessed portions 33U (five in the present embodiment) are continuously provided in the separate patterning direction in the region between two of the emission openings 34 adjacent to each other on the limiting plate 59 side of a top plate 33f.

The recessed portions 33U are each formed into a reverse wedge-like shape and while, in the present embodiment, are formed at a depth of 10 mm and a width in the separate patterning direction of 4 mm, the embodiment is not limited thereto.

Further, while in the present embodiment planar portions are continuously provided every 3.5 mm from each of the emission openings 34 adjacent to each other to the five recessed portions 33U continuously provided therebetween in the separate patterning direction, the embodiment is not limited thereto.

Furthermore, in the present embodiment, extended planes of an inclined face 33a and an inclined face 33b provided to each of the recessed portions 33U in the limiting plate 59 direction intersect both ends in the separate patterning direction of the lower face 59L of the limiting plate 59 that exists directly above the region between the two emission openings 34 adjacent to each other. However, the embodiment is not limited thereto.

Note that the perpendicular lines S of the inclined face 33a and the inclined face 33b provided to each of the recessed portions 33U intersect the lower face 59L of the limiting plate 59.

Thus, the vapor deposition particles vapor-deposited once again from the vapor deposition particle masses 64 in the five recessed portions 33U continuously provided do not spread to the outer side of the extended planes, making it possible to suppress the scattering of vapor deposition particles to areas near the emission opening 34.

That is, the amount of vapor deposition particles that, from the vapor deposition particle mass 64 in each of the recessed portions 33U, reach near to the emission opening 34 can be decreased, and the vapor deposition particle density near the emission opening 34 can be reduced, thereby making it possible to suppress the occurrence of relatively large smudges not intended by design.

FIGS. 11A and 11B are diagrams illustrating a case where the film thickness distribution in the separate patterning direction of the vapor deposition film 35 formed on the substrate 61 without using a vapor deposition mask in the vapor deposition apparatus 30 is normalized, given a maximum film thickness of 1, as illustrated in FIG. 10A.

The alternate long and short dash line in the diagram indicates the design pattern, and this design pattern is an ideal pattern determined by the width of the emission opening 34 in the separate patterning direction, the width of the space between two of the limiting plates 59 adjacent to each other, the distance between the lower face 59L of the limiting plate 59 and the emission opening 34, and the distance between the upper face 59H of the limiting plate 59 and the substrate 61.

The solid line in the diagram is the pattern of the vapor deposition film obtained using the known vapor deposition apparatus illustrated in FIG. 16A, and the dashed line in the figure is the pattern of the vapor deposition film 35 formed on the substrate 61 in the vapor deposition apparatus 30 without using a vapor deposition mask, as illustrated in FIG. 10A.

As illustrated, in the pattern of the vapor deposition film 35 formed on the substrate 61 in the vapor deposition apparatus 30 without using a vapor deposition mask, the smudges not intended by design in the separate patterning direction are small compared to those in the pattern of the vapor deposition film obtained using the known vapor deposition apparatus, resulting in a pattern close to the design pattern, which is the ideal pattern.

Note that while, in the present embodiment, a case where the five recessed portion 33U are continuously provided is used as an example, the embodiment is not limited thereto, and naturally the recessed portions 33U may be non-continuously provided and the number and arranged positions may be changed as appropriate.

### Fourth Embodiment

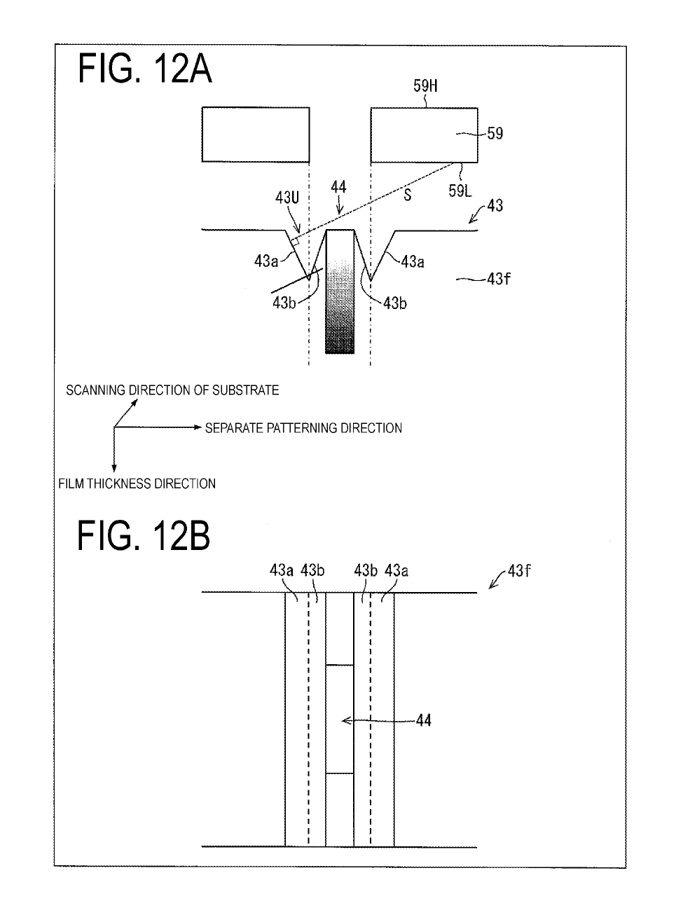

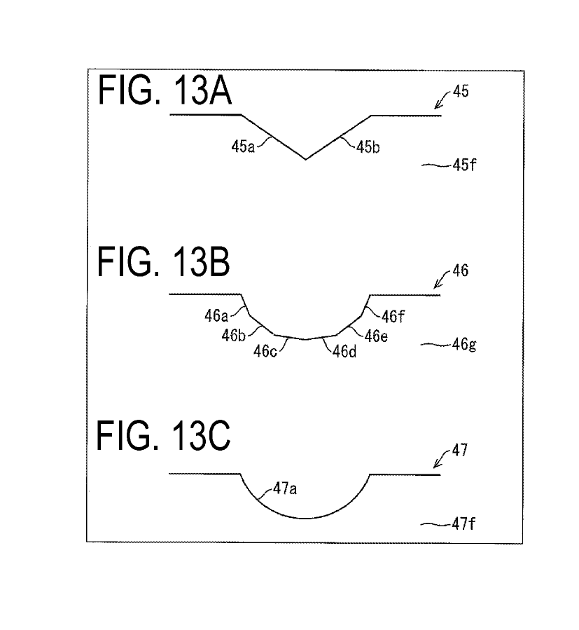

Next, a fourth embodiment of the disclosure will be described with reference to FIGS. 12A to 13C. The present embodiment differs from the first to third embodiments in that a recessed portion 43U is provided near each emission opening 44 in the separate patterning direction of the region between two of the emission openings 44 adjacent to each other. All other components are as described in the first to third embodiments. For convenience of descriptions, members having the same functions as those of the members illustrated in the diagrams in the first to third embodiments are denoted by the same reference numerals, and descriptions thereof will be omitted.

FIG. 12A is a diagram illustrating a vapor deposition particle emitting portion 43.

FIG. 12B is a diagram illustrating the vapor deposition particle emitting portion 43 as viewed from the substrate direction.

As illustrated in FIGS. 12A and 12B, the emission openings 44 are each formed into a shape having a width in the scanning direction of the substrate that is greater than a width in the separate patterning direction.

Then, the recessed portions 43U are each provided near the emission opening 44 of the region between two of the emission openings 44 adjacent to each other in the separate patterning direction, on the limiting plate 59 side of a top plate 43f. That is, two of the recessed portions 43U are provided in the region between two of the emission openings 44 adjacent to each other in the separate patterning direction.

Each of the recessed portions 43U include an inclined face 43a and an inclined face 43b.

The inclined face 43a is inclined, causing the perpendicular line S of a portion of the inclined face 43a to intersect the limiting plates 59 adjacent to, and not directly above, the inclined face 43a in the separate patterning direction, and the inclined face 43b is inclined, causing the perpendicular line S of a portion of the inclined face 43b to intersect the limiting plates 59 adjacent to, and not directly above, the inclined face 43b in the separate patterning direction.

The vapor deposition particles vapor-deposited once again from the vapor deposition particle mass (not illustrated) in the recessed portion 43U provided near the emission opening 44 are prevented from scattering into the spaces between the limiting plates 59 by the inclined face 43a and the inclined face 43b. This is because the vapor deposition particles vapor-deposited once again from the vapor deposition particle mass (not illustrated) on the inclined face 43a and the inclined face 43b are vapor-deposited on the adjacent limiting plates 59 in the separate patterning direction.

Thus, the amount of vapor deposition particles that, from the vapor deposition particle mass in each of the recessed portions 43U, are scattered to the spaces between the limiting plates 59 can be decreased, making it possible to suppress the occurrence of relatively large smudges not intended by design.

Further, the recessed portion 43U includes a region where the region between the two emission openings 44 adjacent to each other and the space between the plurality of limiting plates 59 overlap in a plan view, thereby making it possible to decrease the amount of vapor deposition particles that pass from areas near the emission openings 44 through the spaces between the plurality of limiting plates 59.

Note that, while in the present embodiment an upper side and a lower side of the emission opening 44 are formed by planar faces as illustrated in FIG. 12B, the upper side and the lower side of the emission opening 44 are not limited thereto and may be provided with inclined faces as well.

FIGS. 13A to 13C are diagrams illustrating modifications of the recessed portion that can be provided to vapor deposition particle emitting portions 45, 46, 47.

FIG. 13A is a diagram illustrating a top plate 45f of the vapor deposition particle emitting portion 45, and illustrates an example of a recessed portion including inclined faces 45a, 45b having inclination angles less than those of the inclined face 43a and the inclined face 43b provided to the vapor deposition particle emitting portion 43 illustrated in FIGS. 12A and 12B. Even with such a recessed portion, the amount of vapor deposition particles scattered to the spaces between the limiting plates 59 can be decreased by suitably arranging the limiting plates 59, making it possible to suppress the occurrence of relatively large smudges not intended by design.

FIG. 13B is a diagram illustrating a top plate 46g of the vapor deposition particle emitting portion 46, and illustrates an example of a recessed portion including a plurality of inclined faces 46a, 46b, 46c, 46d, 46e, 46f, each having a different inclination angle. Even with such a recessed portion, the amount of vapor deposition particles scattered to the spaces between the limiting plates 59 can be decreased by suitably arranging the limiting plates 59, making it possible to suppress the occurrence of relatively large smudges not intended by design.

FIG. 13C is a diagram illustrating a top plate 47f of the vapor deposition particle emitting portion 47, and illustrates an example of a recessed portion including an inclined face formed by a curved surface 47a. Even with such a recessed portion, the amount of vapor deposition particles scattered to the spaces between the limiting plates 59 can be decreased by suitably arranging the limiting plates 59, making it possible to suppress the occurrence of relatively large smudges not intended by design.

Note that each of the modifications illustrated in FIGS. 13A to 13C may naturally be used as modifications in the first to third embodiments described above in addition to the present embodiment.

### Fifth Embodiment

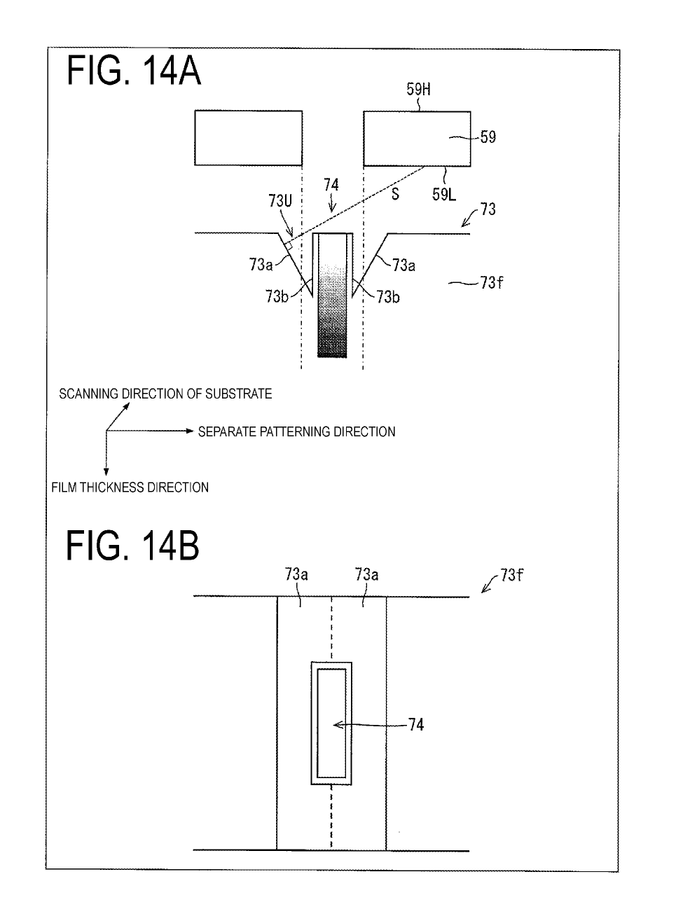

Next, a fifth embodiment of the disclosure will be described below with reference to FIGS. 14A and 14B. The present embodiment differs from the fourth embodiment in that a recessed portion 73U that includes an inclined face 73a near each emission opening 74 and a face 73b perpendicular to the lower face 59L of the limiting plate 59 in the region between two of the emission openings 74 adjacent to each other, in the separate patterning direction. All other components are as described in the fourth embodiment. For convenience of descriptions, members having the same functions as those of the members illustrated in the diagrams in the fourth embodiment are denoted by the same reference numerals, and descriptions thereof will be omitted.

FIG. 14A is a diagram illustrating a vapor deposition particle emitting portion 73.

FIG. 14B is a diagram illustrating the vapor deposition particle emitting portion 73 as viewed from the substrate direction.

As illustrated in FIGS. 14A and 14B, the emission openings 74 are each formed into a shape having a width in the scanning direction of the substrate that is greater than a width in the separate patterning direction.

Then, the recessed portions 73U are each provided near the emission opening 74 of the region between two of the emission openings 74 adjacent to each other in the separate patterning direction, on the limiting plate 59 side of a top plate 73f. That is, two of the recessed portions 73U are provided in the region between two of the emission openings 74 adjacent to each other in the separate patterning direction.

The inclined face 73a provided to each of the recessed portions 73U is inclined, causing the perpendicular line S of a portion of the inclined face 73a to intersect the limiting plate 59 adjacent to, and not directly above, the inclined face 73a in the separate patterning direction.

Note that, as illustrated in FIG. 14B, the inclined face 73a is provided on the upper side and the lower side of the emission opening 74.

The vapor deposition particles vapor-deposited once again from the vapor deposition particle mass (not illustrated) in the recessed portion 73U provided near the emission opening 74 are prevented from scattering into the spaces between the limiting plates 59 by the inclined face 73a. This is because the vapor deposition particles vapor-deposited once again from the vapor deposition particle mass (not illustrated) on the inclined face 73a are vapor-deposited on the adjacent limiting plate 59 in the separate patterning direction.

Thus, the amount of vapor deposition particles that, from the vapor deposition particle mass in each of the recessed portions 73U, are scattered to the spaces between the limiting plates 59 can be decreased, making it possible to suppress the occurrence of relatively large smudges not intended by design.

Further, the recessed portion 73U includes a portion of a region where the region between the two emission openings 74 adjacent to each other and the space between the plurality of limiting plates 59 overlap in a plan view, thereby making it possible to decrease the amount of vapor deposition particles that pass from areas near the emission openings 74 through the spaces between the plurality of limiting plates 59.

### Supplement

The vapor deposition apparatus according to a first aspect of the disclosure includes a vapor deposition particle emitting portion including a top plate linearly provided with a plurality of emission openings, being configured to emit vapor deposition particles, along with a first direction, and a plurality of limiting plates, wherein the plurality of emission openings being positioned in respective space between the plurality of limiting plates. The top plate includes a recessed portion on the limiting plate side, in a second direction orthogonal to the first direction, in a region between two of the emission openings adjacent to each other. The recessed portion includes at least one inclined face inclined with respect to the first direction, causing a perpendicular line perpendicular to at least a portion of the inclined face to intersect the limiting plate.

According to such a configuration, because (a) the recessed portion is provided in the region between two of the emission openings adjacent to each other in the second direction orthogonal to the first direction, (b) the recessed portion includes at least one inclined face inclined with respect to the first direction, and (c) the perpendicular line perpendicular to at least a portion of the inclined face intersects the limiting plate, even when a portion of the vapor deposition particles emitted from the emission openings adhere to the limiting plates and then partially scatter to the limiting plate side of the top plate as a vapor deposition particle mass, and the top plate increases to a temperature higher than a sublimating temperature of a vapor deposition material used in the top plate, in the top plate on the limiting plate side, it is possible to limit the scattering direction of the vapor deposition particles from the vapor deposition particle mass in the recessed portion by the inclined face.

The amount of vapor deposition particles scattered from the vapor deposition particle mass of the recessed portion is greatest in the direction perpendicular to the inclined face, and the vapor deposition particles scattered in this direction adhere to the limiting plate.

Therefore, it is possible to decrease the amount of vapor deposition particles that pass through the spaces between the plurality of limiting plates from areas near the emission openings, and achieve a vapor deposition apparatus capable of suppressing the occurrence of relatively large smudges not intended by design.

According to the vapor deposition apparatus according to a second aspect of the disclosure, in the first aspect, the limiting plate intersected by the perpendicular line of the inclined face may be the limiting plate that exist directly above the region between two of the emission openings adjacent to each other.

According to the configuration described above, it is possible to decrease the amount of vapor deposition particles that pass through the spaces between the plurality of limiting plates from areas near the emission openings, and achieve a vapor deposition apparatus capable of suppressing the occurrence of relatively large smudges not intended by design.

According to the vapor deposition apparatus according to a third aspect of the disclosure, in the first or second aspect, the inclined face may at least partially overlap with one of the spaces between the plurality of limiting plates in plan view.

According to the configuration described above, it is possible to decrease the amount of vapor deposition particles that pass through the spaces between the plurality of limiting plates from areas near the emission openings, and achieve a vapor deposition apparatus capable of suppressing the occurrence of relatively large smudges not intended by design.

According to the vapor deposition apparatus according to a fourth aspect of the disclosure, in the second aspect, the perpendicular line of the inclined face may be configured to intersect the lower face of the limiting plate that exists directly above the region between two of the emission openings adjacent to each other.

According to the configuration described above, it is possible to decrease the amount of vapor deposition particles that pass through the spaces between the plurality of limiting plates from areas near the emission openings, and achieve a vapor deposition apparatus capable of suppressing the occurrence of relatively large smudges not intended by design.

According to the vapor deposition apparatus according to a fifth aspect of the disclosure, in any one of the first, second or fourth aspects, extended planes extending from the inclined faces in the limiting plate direction may respectively intersect both ends in the first direction of the lower face of the limiting plate that exists directly above the region between two of the emission openings adjacent to each other.

According to the configuration described above, the vapor deposition particles vapor-deposited once again from the vapor deposition particle mass in the recessed portion do not spread to the outer side of the extended planes, making it possible to decrease the amount of vapor deposition particles that pass through the spaces between the plurality of limiting plates from areas near the emission openings, and achieve a vapor deposition apparatus capable of suppressing the occurrence of relatively large smudges not intended by design.

According to the vapor deposition apparatus according to a sixth aspect of the disclosure, in the first aspect, the recessed portion may be formed by a plurality of inclined faces, each having a different inclination angle.

According to such a configuration, the amount of vapor deposition particles that, from the vapor deposition particle mass in the recessed portion formed by the plurality of inclined faces each having a different inclination angle, reach near to the emission opening can be decreased, and the vapor deposition particle density near the emission opening can be reduced, thereby making it possible to achieve a vapor deposition apparatus capable of suppressing the occurrence of relatively large smudges not intended by design.

According to the vapor deposition apparatus according to a seventh aspect of the disclosure, in the first aspect, the recessed portion may be formed by a curved surface.

According to such a configuration, the amount of vapor deposition particles that, from the vapor deposition particle mass in the recessed portion formed by a curved surface, reach near to the emission opening can be decreased, and the vapor deposition particle density near the emission opening can be reduced, thereby making it possible to achieve a vapor deposition apparatus capable of suppressing the occurrence of relatively large smudges not intended by design.

According to the vapor deposition apparatus according to an eighth aspect of the disclosure, in any one of the first to seventh aspects, a plurality of the recessed portions are preferably provided in the region between two of the emission openings adjacent to each other in the first direction.

According to such a configuration, the amount of vapor deposition particles that, from the vapor deposition particle mass in the plurality of recessed portions, reach near to the emission opening can be decreased, and the vapor deposition particle density near the emission opening can be reduced, thereby making it possible to achieve a vapor deposition apparatus capable of suppressing the occurrence of relatively large smudges not intended by design.

According to the vapor deposition apparatus according to a ninth aspect of the disclosure, in any one of the first to eighth aspects, the recessed portion is preferably provided symmetrically in the first direction about the emission opening.

According to such a configuration, it is possible to achieve a vapor deposition apparatus capable of forming a more uniform vapor deposition film.

According to the vapor deposition apparatus according to a tenth aspect of the disclosure, in any one of the first to ninth aspects, each of the plurality of emission openings has a width in the second direction that is greater than a width in the first direction.

According to such a configuration, it is possible to achieve a vapor deposition apparatus capable of forming a vapor deposition film that is linear in the second direction.

According to the vapor deposition apparatus according to an eleventh aspect of the disclosure, in any one of the first to tenth aspects, the vapor deposition particle emitting portion, the plurality of limiting plates, a vapor deposition mask, and a substrate are disposed in the described order from a bottom.

According to the configuration described above, it is possible to achieve a vapor deposition apparatus capable of suppressing the occurrence of relatively large smudges not intended by design when a vapor deposition film is formed on the substrate via the limiting plates and the vapor deposition mask.

According to the vapor deposition apparatus according to a twelfth aspect of the disclosure, in the eleventh aspect, the substrate or a vapor deposition unit that includes the vapor deposition particle emitting portion, the plurality of limiting plates, and the vapor deposition mask may be configured to move in the second direction.

According to the configuration described above, it is possible to achieve a vapor deposition apparatus that can be used in scan vapor deposition.

According to the vapor deposition apparatus according to a thirteenth aspect of the disclosure, in any one of the first to twelfth aspects, the emission openings may protrude to the limiting plate side of the top plate of the vapor deposition particle emitting portion.

According to the configuration described above, it is possible to achieve a vapor deposition apparatus capable of suppressing the occurrence of relatively large smudges not intended by design.

To solve the above-described problems, a vapor deposition method according to the disclosure includes arranging a vapor deposition particle emitting portion including a top plate linearly provided with a plurality of emission openings, being configured to emit vapor deposition particles, along with a first direction, a plurality of limiting plates, a vapor deposition mask, and a substrate in the described order from a bottom, and vapor-depositing vapor deposition particles emitted from the vapor deposition particle emitting portion on the substrate via spaces between the plurality of limiting plates and openings in the vapor deposition mask. The vapor-depositing is performed with the limiting plate disposed as a perpendicular line perpendicular to at least a portion of the inclined face to intersect the limiting plate with respect to a recessed portion being provided in a region between two of the emission openings adjacent to each other on the limiting plate side of the top plate, in a second direction orthogonal to the first direction, and including at least one inclined face inclined with respect to the first direction.

According to the vapor deposition method described above, the vapor-depositing is performed with the limiting plate disposed with respect to the recessed portion that is provided in the region between two of the emission openings adjacent to each other on the limiting plate side of the top plate, in the second direction orthogonal to the first direction, and that includes at least one inclined face inclined with respect to the first direction, causing a perpendicular line perpendicular to at least a portion of the inclined face to intersect the limiting plate, thereby making it possible to decrease the amount of vapor deposition particles that pass from areas near the emission openings through the plurality of limiting plates, and achieve a vapor deposition method capable of suppressing the occurrence of relatively large smudges not intended by design.

The method for manufacturing an organic EL display device according to the disclosure is a method including a forming step of a vapor deposition layer for an organic EL element including arranging a vapor deposition particle emitting portion including a top plate linearly provided with a plurality of emission openings, being configured to emit vapor deposition particles, along with a first direction, a plurality of limiting plates, a vapor deposition mask, and a substrate in the described order from a bottom, and vapor-depositing vapor deposition particles emitted from the vapor deposition particle emitting portion on the substrate via spaces between the plurality of limiting plates and openings in the vapor deposition mask. The vapor-depositing is performed, in the forming step of the vapor deposition layer for the organic EL element, with the limiting plate disposed as a perpendicular line perpendicular to at least a portion of the inclined face to intersect the limiting plate with respect to a recessed portion being provided in a region between two of the emission openings adjacent to each other on the limiting plate side of the top plate, in a second direction orthogonal to the first direction, and including at least one inclined face inclined with respect to the first direction.

According to the method for manufacturing an organic EL display device described above, in the organic EL element vapor deposition layer forming step, the vapor-depositing is performed with the limiting plate disposed with respect to the recessed portion that is provided in the region between two of the emission openings adjacent to each other on the limiting plate side of the top plate, in the second direction orthogonal to the first direction, and includes at least one inclined face inclined with respect to the first direction, causing a perpendicular line perpendicular to at least a portion of the inclined face to intersect the limiting plate, thereby making it possible to decrease the amount of vapor deposition particles that pass from areas near the emission openings through the plurality of limiting plates, and achieve a method for manufacturing an organic EL display device capable of suppressing the occurrence of relatively large smudges not intended by design.

According to a method for manufacturing an organic EL display device according to a sixteenth aspect of the disclosure, in the fifteenth aspect, the organic EL element vapor deposition layer forming step may be a light-emitting layer vapor-depositing step.

According to the method described above, it is possible to vapor-deposit a light-emitting layer while suppressing the occurrence of relatively large smudges not intended by design.

### Additional Items

The disclosure is not limited to each of the embodiments stated above, and various modifications may be implemented within a range not departing from the scope of the claims. Embodiments obtained by appropriately combining technical approaches stated in each of the different embodiments also fall within the scope of the technology of the disclosure. Moreover, novel technical features may be formed by combining the technical approaches stated in each of the embodiments.

### INDUSTRIAL APPLICABILITY

The disclosure can be used for a vapor deposition apparatus, a vapor deposition method, and a method for manufacturing an organic EL display device.

### REFERENCE SIGNS LIST

1 Vapor deposition apparatus
3 Vapor deposition particle emitting portion
3a Inclined face
3b Inclined face
3f Top plate
3S Planar face
3U Recessed portion
4 Emission opening
5 Vapor deposition unit
11 Vapor deposition film
12 Vapor deposition film
12R Red light-emitting layer
12G Green light-emitting layer
12B Blue light-emitting layer
13 Vapor deposition particle emitting portion
13a Inclined face
13b Inclined face
13f Top plate
13S Planar face
13U Recessed portion
14 Emission opening
20 Vapor deposition apparatus
23 Vapor deposition particle emitting portion
23a Inclined face
23b Inclined face
23f Top plate
23U Recessed portion
24 Emission opening
25 Vapor deposition film
30 Vapor deposition apparatus
33 Vapor deposition particle emitting portion
33a Inclined face
33b Inclined face
33f Top plate
33U Recessed portion
34 Emission opening
35 Vapor deposition film
43 Vapor deposition particle emitting portion
43a Inclined face
43b Inclined face
43f Top plate
43U Recessed portion
44 Emission opening
45 Vapor deposition particle emitting portion
45a Inclined face
45b Inclined face
45f Top plate
46 Vapor deposition particle emitting portion
46a Inclined face
46b Inclined face
46c Inclined face
46d Inclined face
46e Inclined face
46f Inclined face
46g Top plate
47 Vapor deposition particle emitting portion
47a Curved surface
47f Top plate
52 Vacuum chamber
54 Vapor deposition source
59 Limiting plate
59L Lower face of limiting plate
59H Upper face of limiting plate
60 Vapor deposition mask
60K Opening
61 Substrate
64 Vapor deposition particle mass
73 Vapor deposition particle emitting portion
73a Inclined face
73b Surface perpendicular to lower face of limiting plate
73f Top plate
73U Recessed portion
74 Emission opening
S Perpendicular line

1. A vapor deposition apparatus comprising:
a vapor deposition particle emitting portion including a top plate linearly provided with a plurality of emission openings, being configured to emit vapor deposition particles, along with a first direction; and
a plurality of limiting plates,
wherein the plurality of emission openings are positioned in respective space between the plurality of limiting plates,
the top plate includes a recessed portion on the limiting plate side, in a second direction orthogonal to the first direction, in a region between two of the emission openings adjacent to each other,
the recessed portion includes at least one inclined face inclined with respect to the first direction, and
a perpendicular line perpendicular to at least a portion of the inclined face intersects the limiting plate.

2. The vapor deposition apparatus according to claim 1,
wherein the limiting plate intersected by the perpendicular line of the inclined face exists directly above the region between two of the emission openings adjacent to each other.

3. The vapor deposition apparatus according to claim 1,
wherein the inclined face at least partially overlaps with one of the spaces between the plurality of limiting plates in a plan view.

4. The vapor deposition apparatus according to claim 2,
wherein the perpendicular line of the inclined face intersects a lower face of the limiting plate that exists directly above the region between two of the emission openings adjacent to each other.

5. The vapor deposition apparatus according to claim 1,
wherein extended planes extending from the inclined faces in the limiting plate direction respectively intersect both ends in the first direction of the lower face of the limiting plate that exists directly above the region between two of the emission openings adjacent to each other.

6. The vapor deposition apparatus according to claim 1,
wherein the recessed portion includes a plurality of inclined faces, each having a different inclination angle.

7. The vapor deposition apparatus according to claim 1,
wherein the recessed portion is formed by a curved surface.

8. The vapor deposition apparatus according to claim 1,
wherein a plurality of the recessed portions are provided in the first direction in the region between two of the emission openings adjacent to each other.

9. The vapor deposition apparatus according to claim 1,
wherein the recessed portion is provided symmetrically in the first direction about the emission opening.

10. The vapor deposition apparatus according to claim 1,
wherein each of the plurality of emission openings has a width in the second direction that is greater than a width in the first direction.

11. The vapor deposition apparatus according to claim 1,
wherein the vapor deposition particle emitting portion, the plurality of limiting plates, a vapor deposition mask, and a substrate are disposed in the described order from a bottom.

12. The vapor deposition apparatus according to claim 11,
wherein the substrate or a vapor deposition unit including the vapor deposition particle emitting portion, the plurality of limiting plates, and the vapor deposition mask is configured to move in the second direction.

13. The vapor deposition apparatus according to claim 1,
wherein the emission openings protrude to the limiting plate side of the top plate of the vapor deposition particle emitting portion.

14. A vapor deposition method comprising:
arranging a vapor deposition particle emitting portion including a top plate linearly provided with a plurality of emission openings, being configured to emit vapor deposition particles, along with a first direction, a plurality of limiting plates, a vapor deposition mask, and a substrate in the described order from a bottom; and
vapor-depositing vapor deposition particles emitted from the vapor deposition particle emitting portion on the substrate via spaces between the plurality of limiting plates and openings in the vapor deposition mask,
wherein the vapor-depositing is performed with the limiting plate disposed as a perpendicular line perpendicular to at least a portion of the inclined face to intersect the limiting plate with respect to a recessed portion being provided in a region between two of the emission openings adjacent to each other on the limiting plate side of the top plate, in a second direction orthogonal to the first direction, and including at least one inclined face inclined with respect to the first direction.

15. A method for manufacturing an organic EL display device comprising:
a forming step of a vapor deposition layer for an organic EL element including
arranging a vapor deposition particle emitting portion including a top plate linearly provided with a plurality of emission openings, being configured to emit vapor deposition particles, along with a first direction, a plurality of limiting plates, a vapor deposition mask, and a substrate in the described order from a bottom; and
vapor-depositing vapor deposition particles emitted from the vapor deposition particle emitting portion on the substrate via spaces between the plurality of limiting plates and openings in the vapor deposition mask,
wherein vapor-depositing is performed, in the forming step of the vapor deposition layer for the organic EL element, with the limiting plate disposed as a perpendicular line perpendicular to at least a portion of the inclined face to intersect the limiting plate with respect to a recessed portion being provided in a region between two of the emission openings adjacent to each other on the limiting plate side of the top plate, in a second direction orthogonal to the first direction, and including at least one inclined face inclined with respect to the first direction.

16. The method for manufacturing an organic EL display device according to claim 15,
wherein the forming step of the vapor deposition layer for the organic EL element includes a light-emitting layer vapor-depositing step.
